(19) United States
(12) Patent Application Publication
(10) Pub. No.: US 2013/0292719 A1
(43) Pub. Date: Nov. 7, 2013

(54) LIGHT-EMITTING DIODE STRUCTURE AND METHOD FOR MANUFACTURING THE SAME

(71) Applicant: CHI MEI LIGHTING TECHNOLOGY CORP., Tainan (TW)

(72) Inventors: Hsueh Lin Lee, Tainan (TW); Chang Hsin Chu, Tainan (TW); Yuan Tze Chen, Tainan (TW); Chih Kuei Hsu, Tainan (TW)

(73) Assignee: CHI MEI LIGHTING TECHNOLOGY CORP., Tainan (TW)

(21) Appl. No.: 13/886,588

(22) Filed: May 3, 2013

(30) Foreign Application Priority Data
May 4, 2012 (TW) 101116039
Aug. 3, 2012 (TW) 101128042
Apr. 12, 2013 (TW) 102113113

(51) Int. Cl. H01L 33/08

(52) U.S. Cl. CPC H01L 33/08
USPC 257/93; 438/29

(57) ABSTRACT

A light-emitting diode (LED) structure includes an insulation substrate; LED chips each includes an epitaxial layer having a first conductivity type semiconductor layer, an active layer, and a second conductivity type semiconductor layer stacked on the insulation substrate, and comprises a mesa structure and an exposed portion of the first conductivity type semiconductor layer adjacent to each other, and a first isolation trench within the mesa structure; interconnection layers connect the LED chips; electrode pads respectively connected to exposed portions of the semiconductor layers; a reflective insulating layer covering the interconnection layers, the mesa structures and the electrode pads, and having penetration holes respectively exposing a portion of the electrode pads; and bonding pads located on a portion of the reflective insulating layer and connected to the electrode pads through the penetrating holes. A method of manufacturing the LED structure.

### CROSS-REFERENCE TO RELATED APPLICATIONS

This non-provisional application claims priority under 35 U.S.C. §119(a) on Patent Application Nos. 101116039 filed in Taiwan, R.O.C. on May 4, 2012, 101128042 filed in Taiwan, R.O.C. on Aug. 3, 2012, and 102113113 filed in Taiwan, R.O.C. on Apr. 12, 2013, the entire contents of which are hereby incorporated by reference.

### FIELD OF THE INVENTION

The present invention relates to a light-emitting structure, and more particularly to a light-emitting diode (LED) structure and a method for manufacturing the same.

### BACKGROUND OF THE INVENTION

Nowadays, to enhance the overall light emission efficiency of an LED, it is developed to connecting a plurality of LED chips in series in a wire bonding manner. As a wire bonding manner has the problems of high cost and a low production yield, it is further developed to connect a plurality of LED chips in series by embedding a metal.

FIG. 1 is a partial sectional view of a conventional serially-connected LED structure. In this conventional serially-connected LED structure 100, a plurality of LED chips is connected in series by embedding a metal. The serially-connected LED structure 100 includes a plurality of LED chips connected in series, for example, LED chips 106a and 106b. These LED chips 106a and 106b are disposed on the surface 104 of an insulation substrate 102. Two adjacent LED chips 106a and 106b are separated by an isolation trench 122. The LED chips 106a and 106b each include an undoped semiconductor layer 108, a first conductivity type semiconductor layer 110, an active layer 112, a second conductivity type semiconductor layer 114, and a transparent conductive layer 116 sequentially stacked on the surface of the insulation substrate 102.

Both the LED chips 106a and 106b have a mesa structure 128 and an exposed portion 130 of the first conductivity type semiconductor layer 110. A first conductive type electrode pad 118a and a second conductive type electrode pad 120a of an LED chip 106a are disposed on the exposed portion 130 of the first conductivity type semiconductor layer 110 and the mesa structure 128, respectively. Similarly, a first conductive type electrode pad 118b and a second conductive type electrode pad 120b of an LED chip 106b is disposed on the exposed portion 130 of the first conductivity type semiconductor layer 110 and the mesa structure 128, respectively.

In the LED structure 100, an insulating layer 124 covers the isolation trench 122, and extends on the first conductivity type semiconductor layer 110 of the LED chip 106a and on the transparent conductive layer 116 of the LED chip 106b outside the opening of the isolation trench 122, so as to electrically isolate the two adjacent LED chips 106a and 106b. To connect the two adjacent LED chips 106a and 106b in series, the LED structure 100 has an interconnection layer 126. The interconnection layer 126 extends, from the first conductive type electrode pad 118a of the LED chip 106a, through the insulating layer 124 above the exposed portion 130 of the first conductivity type semiconductor layer 110 and inside the isolation trench 122, to the insulating layer 124 and the second conductive type electrode pad 120b of the adjacent LED chip 106b, so as to electrically connect the adjacent LED chips 106a and 106b in series.

Because such a serially connected LED structure 100 is driven by a relatively high voltage, a drive circuit has relatively high efficiency. Further, comparing with a plurality of independent LED chips, the serially connected LED structure 100 has a small area of electrode pads, so that the LED structure 100 has a relatively large light emission area. Furthermore, because the current in the serially connected LED structure 100 can flow in a scattered manner in each of the small LED chips, the current distribution is more uniform than a single large area LED chip, and therefore the serially connected LED structure 100 has higher light emission efficiency.

However, because the bottom of the isolation trench 122 of such a conventional serially connected LED structure 100 extends downwardly to the surface 104 of the insulation substrate 102. Therefore, the aspect ratio of the isolation trench 122 is too high, the material of the insulating layer 124 cannot be filled easily, and discontinuous deposition occurs easily, which easily causes broken holes in the insulating layer 124. Therefore, during subsequent deposition of the conductive interconnection layer 126, the conductive material of the interconnection layer 126 might be filled in the broken holes of the insulating layer 124, which results in a short circuit.

In a serially connected LED structure 100, as long as a short circuit occurs on one LED chip 106a or 106b, the entire serially connected LED structure 100 fails to work. Therefore, the production yield of the serially connected LED structure 100 is undesirable.

In addition, a very high aspect ratio of the isolation trench 122 might easily causes discontinuous deposition of the interconnection layer 126, resulting in disconnection of the interconnection layer 126. In the serially connected LED structure 100, as long as a disconnection phenomenon occurs on one LED chip 106a or 106b, the entire serially connected LED structure 100 also fails to work. Therefore, the production yield of such a serially connected LED structure 100 is undesirable.

Therefore, a heretofore unaddressed need exists in the art to address the aforementioned deficiencies and inadequacies.

### SUMMARY OF THE INVENTION

In one aspect, the present invention is directed to an LED structure formed by connecting a plurality of LED chips in series and has the advantages such as dense arrangement and high light efficiency.

In another aspect, the present invention is directed to an LED structure and a method for manufacturing the same, in which a reflective insulating layer covers an interconnection layer, a mesa structure and an exposed portion of a first conductivity type semiconductor layer, so as to perform packaging in a flip chip manner, thereby achieving the efficacies such as high heat dissipation, being free of wire bonding, and low thermal resistance.

In yet another aspect, the present invention is directed to an LED structure and a method for manufacturing the same, in which an interconnection layer extends, from an exposed portion of a first conductivity type semiconductor layer of one of adjacent LED chips, directly through the side of the mesa structure of another adjacent LED chip, and onto the mesa structure. Therefore, the aspect ratio of an interconnection layer can be significantly reduced, thereby effectively enhancing the step coverage capability during the deposition of the interconnection layer and further avoiding the occurrence of disconnections during the deposition of the interconnection layer.

In a further aspect, the present invention is directed to an LED structure and a method for manufacturing the same, in which a mesa structure of an LED chip has a inclined trapezoidal side, so as to further enhance the step coverage capability of an interconnection layer and solve the problem of disconnections of the interconnection layer more effectively.

In a further aspect, the present invention is directed to an LED structure and a method for manufacturing the same, in which a light emission area of an LED chip and a first conductivity type semiconductor layer of an adjacent LED chip are separated by an isolation trench, and only an insulating layer, but no conductive material, is filled in the isolation trench. Furthermore, a current blocking layer is, for example, additionally disposed on the opening of the isolation trench to implement electrical isolation. Therefore, even if the insulating layer deposition inside the isolation trench is discontinuous, in the case of no conductive material inside the isolation trench, the short circuit problem in the light emission area is prevented.

In a further aspect, the present invention is directed to an LED structure and a method for manufacturing the same, in which an interconnection layer directly extends, from a contact hole in a dielectric layer above one of adjacent LED chips, through above the dielectric layer, to a contact hole in a dielectric layer above another of the adjacent LED chips. Therefore, a conductive material does not need to be filled in an isolation trench between two adjacent LED chips, thereby solving the problem of disconnections of an interconnection layer.

In a further aspect, the present invention is directed to an LED structure and a method for manufacturing the same, which can effectively solve the problems of short circuits and disconnections, so as to significantly enhance the production yield of the serially-connected LED structure and further reduce fabrication cost.

In a further aspect, the present invention is directed to an LED structure and a method for manufacturing the same, which can effectively solve the problems of short circuits and disconnections, so as to successfully confirm a short circuit defect in an LED structure by detecting forward/reverse currents without depending on a means of detecting a reverse leakage current.

In one embodiment of the present invention, an LED structure includes an insulation substrate, a plurality of LED chips, a plurality of interconnection layers, a first conductive type electrode pad, a second conductive type electrode pad, a reflective insulating layer, a first conductive type bonding pad, and a second conductive type bonding pad. Each LED chip includes an epitaxial layer, and the epitaxial layer includes a first conductivity type semiconductor layer, an active layer, and a second conductivity type semiconductor layer sequentially stacked on the surface of the insulation substrate. Each LED chip further includes a mesa structure, an exposed portion of the first conductivity type semiconductor layer neighboring to the mesa structure, and a first isolation trench in a first direction. The first isolation trench is provided in the mesa structure. The plurality of interconnection layers connects two adjacent LED chips, respectively. The first conductive type electrode pad and the second conductive type electrode pad are disposed on a first LED chip and a second LED chip, respectively, and are electrically connected to the exposed portion of the first conductivity type semiconductor layer of the first LED chip and the second conductivity type semiconductor layer of the second LED chip, respectively. The reflective insulating layer covers the interconnection layer, the mesa structure, the first conductive type electrode pad, and the second conductive type electrode pad. The reflective insulating layer has at least one first penetration hole and at least one second penetration hole exposing a portion of the first conductive type electrode pad and a portion of the second conductive type electrode pad, respectively. The first conductive type bonding pad is located on a portion of the reflective insulating layer and is electrically connected to the first conductive type electrode pad through at least one first penetration hole. The second conductive type bonding pad is located on another portion of the reflective insulating layer and is separated from the first conductive type bonding pad, and is electrically connected to the second conductive type electrode pad through at least one second penetration hole.

In certain embodiments, each LED chip above further includes an insulating layer, and the insulating layer is filled in the first isolation trench to seal an opening of the first isolation trench.

In certain embodiments, each LED chip above further includes a current blocking layer between the interconnection layer on the mesa structure and the insulating layer.

In certain embodiments, each LED chip above further includes a transparent conductive layer extending on the second conductivity type semiconductor layer of the mesa structure and between the interconnection layer and the current blocking layer on the mesa structure.

In certain embodiments, each LED chip above further includes a dielectric layer disposed on the epitaxial layer, and each LED chip is provided with a first electrical contact hole and a second electrical contact hole penetrating the dielectric layer. In addition, the first isolation trench is between the second electrical contact hole of the LED chip and the first electrical contact hole of an adjacent LED chip. Moreover, each interconnection layer extends, from the second electrical contact hole of each LED chip, above the first isolation trench, into the first electrical contact hole of the adjacent LED chip. Also, the reflective insulating layer further covers the dielectric layer.

In certain embodiments, each LED chip above further includes a transparent conductive layer between the dielectric layer and the epitaxial layer. Further, the bottom of the first electrical contact hole exposes the exposed portion of the first conductivity type semiconductor layer, and the bottom of the second electrical contact hole exposes the transparent conductive layer.

In certain embodiments, each LED chip above further includes at least one current blocking layer between the bottom of the second electrical contact hole and the epitaxial layer.

In certain embodiments, in each LED chip above, the epitaxial layer has a groove, the bottom of the groove exposes the exposed portion of the first conductivity type semiconductor layer, the first electrical contact hole exposes a portion of the bottom of the groove, and the dielectric layer covers a sidewall of the groove.

In certain embodiments, each LED chip above further includes at least one insulating lining layer covering a sidewall of the first electrical contact hole.

In another embodiment, a method for manufacturing an LED structure includes following steps. An insulation substrate is provided. An epitaxial structure is formed. The epitaxial structure includes a first conductivity type semiconductor layer, an active layer, and a second conductivity type semiconductor layer sequentially stacked on the surface of the insulation substrate. A plurality of first isolation trenches in a first direction and a plurality of second isolation trenches in a second direction are formed in the epitaxial structure, so as to define a plurality of epitaxial layers of a plurality of LED chips. The first isolation trenches abut the second isolation trenches, respectively. A portion of the second conductivity type semiconductor layer and a portion of the active layer are removed to define a mesa structure and an exposed portion of the first conductivity type semiconductor layer of each LED chip. Each LED chip includes a first isolation trench, and the first isolation trench is provided in the mesa structure. A plurality of interconnection layers, a first conductive type electrode pad, and a second conductive type electrode pad, are formed. These interconnection layers connect two adjacent LED chips, respectively. The first conductive type electrode pad and the second conductive type electrode pad are disposed on a first LED chip and a second LED chip of these LED chips, respectively, and the first conductive type electrode pad and the second conductive type electrode pad are electrically connected to the exposed portion of the first conductivity type semiconductor layer of the first LED chip and the second conductivity type semiconductor layer of the second LED chip, respectively. A reflective insulating layer is formed covering the interconnection layer, the mesa structure, the first conductive type electrode pad, and the second conductive type electrode pad. The reflective insulating layer has at least one first penetration hole and at least one second penetration hole exposing a portion of the first conductive type electrode pad and a portion of the second conductive type electrode pad, respectively. A first conductive type bonding pad is formed on a portion of the reflective insulating layer. The first conductive type bonding pad is electrically connected to the first conductive type electrode pad through at least one first penetration hole. A second conductive type bonding pad is formed on another portion of the reflective insulating layer. The second conductive type bonding pad and the first conductive type bonding pad are separated. Also, the second conductive type bonding pad is electrically connected to the second conductive type electrode pad through at least one second penetration hole.

In certain embodiments, after the first isolation trench and the second isolation trench are formed in the epitaxial structure, the method for manufacturing an LED structure above further includes forming a plurality of dielectric layers covering the epitaxial layer, respectively. Each LED chip has a first electrical contact hole and a second electrical contact hole penetrating the dielectric layer, and the first isolation trench is between the second electrical contact hole of the LED chip and the first electrical contact hole of an adjacent LED chip.

In certain embodiments, before the dielectric layer is formed, the method for manufacturing an LED structure above further includes: forming a plurality of transparent conductive layers between the dielectric layer and the epitaxial layer, respectively; and forming a plurality of current blocking layers located between the epitaxial layer and the transparent conductive layer, respectively. In each LED chip, the bottom of the first electrical contact hole exposes the first conductivity type semiconductor layer, and the bottom of the second electrical contact hole exposes the transparent conductive layer. These current blocking layers are correspondingly disposed at the positions below the bottom of the foregoing second electrical contact hole.

In one embodiment, an LED structure includes an insulation substrate, a plurality of LED chips, a plurality of interconnection layers, a first conductive type electrode pad, a second conductive type electrode pad, an insulating layer, a first conductive type bonding pad, and a second conductive type bonding pad. Each LED chip includes an epitaxial layer. The epitaxial layer includes a first conductivity type semiconductor layer, an active layer, and a second conductivity type semiconductor layer sequentially stacked on the surface of the insulation substrate, and each LED chip includes the mesa structure and the exposed portion of the first conductivity type semiconductor layer adjacent to each other, and a first isolation trench. The first isolation trench is provided in the mesa structure. The plurality of interconnection layers connects two adjacent LED chips, respectively. The first conductive type electrode pad and the second conductive type electrode pad are disposed on a first LED chip and a second LED chip of the LED chips, respectively, and are electrically connected to the exposed portion of the first conductivity type semiconductor layer of the first LED chip and the second conductivity type semiconductor layer of the second LED chip, respectively. The insulating layer covers the interconnection layer, the mesa structure, the first conductive type electrode pad, and the second conductive type electrode pad. The insulating layer has at least one first penetration hole and at least one second penetration hole exposing a portion of the first conductive type electrode pad and a portion of the second conductive type electrode pad. The first conductive type bonding pad is located on a portion of the insulating layer, and is electrically connected to the first conductive type electrode pad through at least one first penetration hole. The second conductive type bonding pad is located on another portion of the insulating layer, is separated from the first conductive type bonding pad, and is electrically connected to the second conductive type electrode pad through at least one second penetration hole.

In certain embodiments, the above insulating layer is a distributed Bragg reflector (DBR).

In certain embodiments, the above LED structure further includes a reflective insulating layer. Each LED chip further includes a dielectric layer disposed on the epitaxial layer. Each LED chip is provided with a first electrical contact hole and a second electrical contact hole penetrating the dielectric layer. The first isolation trench is between the second electrical contact hole of an LED chip and the first electrical contact hole of an adjacent LED chip. The reflective insulating layer covers a sidewall of the first electrical contact hole of each LED chip, a sidewall of the second electrical contact hole, and an upper surface of the dielectric layer. Each interconnection layer extends, from the second electrical contact hole of each LED chip, above the first isolation trench, into the first electrical contact hole of the adjacent LED chip.

In certain embodiments, the above LED structure further includes a reflective insulating layer. Each LED chip further includes a dielectric layer disposed on the epitaxial layer. Each LED chip is provided with a first electrical contact hole and a second electrical contact hole penetrating the dielectric layer. The first isolation trench is between the second electrical contact hole of an LED chip and the first electrical contact hole of an adjacent LED chip. The epitaxial layer has a groove, and the bottom of the groove exposes the exposed portion of the first conductivity type semiconductor layer. The first electrical contact hole exposes a portion of the bottom of the groove. The reflective insulating layer covers a sidewall of each groove and an upper surface of each epitaxial layer. Each interconnection layer extends, from the second electrical contact hole of each LED chip, above the first isolation trench, into the first electrical contact hole of an adjacent LED chip.

In certain embodiments, the above LED structure further includes a reflective insulating layer. Each LED chip further includes a dielectric layer disposed on the epitaxial layer. Each LED chip is provided with a first electrical contact hole and a second electrical contact hole penetrating the dielectric layer. The first isolation trench is between the second electrical contact hole of an LED chip and the first electrical contact hole of an adjacent LED chip. The epitaxial layer has a groove, the bottom of the groove exposes the exposed portion of the first conductivity type semiconductor layer, and the first electrical contact hole exposes a portion of the bottom of the groove. The dielectric layer covers a sidewall of the groove. The reflective insulating layer covers an upper surface of each epitaxial layer. Each interconnection layer extends, from the second electrical contact hole of each LED chip, above the first isolation trench, into the first electrical contact hole of an adjacent LED chip.

In certain embodiments, the above LED structure further includes a reflective insulating layer. Each LED chip further includes a dielectric layer disposed on the epitaxial layer. Each LED chip is provided with a first electrical contact hole and a second electrical contact hole penetrating the dielectric layer. The first isolation trench is between the second electrical contact hole of an LED chip and the first electrical contact hole of an adjacent LED chip. The epitaxial layer has a groove, the bottom of the groove exposes the exposed portion of the first conductivity type semiconductor layer, and the first electrical contact hole exposes a portion of the bottom of the groove. The dielectric layer covers a sidewall of the groove. The reflective insulating layer covers an upper surface of each dielectric layer. The each interconnection layer extends, from the second electrical contact hole of each LED chip, above the first isolation trench, and into the first electrical contact hole of an adjacent LED chip.

These and other aspects of the present invention will become apparent from the following description of the preferred embodiment taken in conjunction with the following drawings, although variations and modifications therein may be effected without departing from the spirit and scope of the novel concepts of the disclosure.

### BRIEF DESCRIPTION OF THE DRAWINGS

The accompanying drawings illustrate one or more embodiments of the invention and together with the written description, serve to explain the principles of the invention. Wherever possible, the same reference numbers are used throughout the drawings to refer to the same or like elements of an embodiment, and wherein:

FIG. 1 is a partial sectional view of a conventional serially-connected LED structure;

FIG. 2 is a schematic top view of an LED structure according to an embodiment of the present invention;

FIG. 3 is a sectional view of the LED structure along a sectional line AA′ in FIG. 2;

FIG. 4 is a sectional view of the LED structure along a sectional line BB′ in FIG. 2;

FIG. 5 is a sectional view of an LED structure according to another embodiment of the present invention;

FIG. 6 is a sectional view of an LED structure according to yet another embodiment of the present invention;

FIG. 7 is a sectional view of an LED structure according to a further embodiment of the present invention;

FIG. 8 is a sectional view of an LED structure according to a further embodiment of the present invention;

FIG. 9 is a sectional view of an LED structure according to a further embodiment of the present invention;

FIG. 10 is a sectional view of an LED structure according to a further embodiment of the present invention;

FIG. 11A to FIG. 11G are process sectional views of an LED structure according to an embodiment of the present invention;

FIG. 12A to FIG. 12D are process sectional views of an LED structure according to another embodiment of the present invention; and

FIG. 13A to FIG. 13C are process sectional views of an LED structure according to a further embodiment of the present invention.

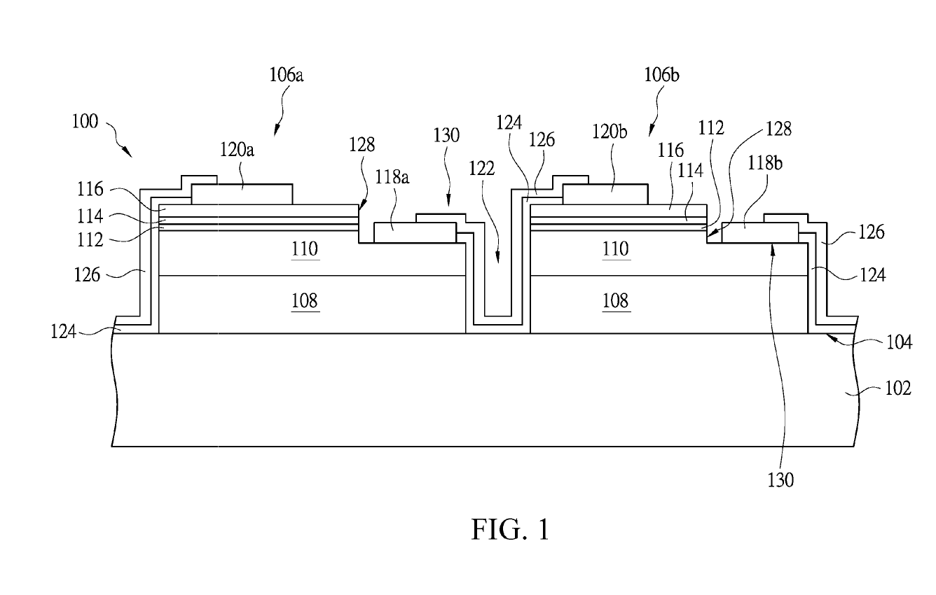

### DETAILED DESCRIPTION OF THE INVENTION

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Example embodiments are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments should not be construed as limited to the shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

It will be understood that when an element or layer is referred to as being “on,” “connected to,” “coupled to,” or “covering” another element or layer, it may be directly on, connected to, coupled to, or covering the other element or layer or intervening elements or layers may be present. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

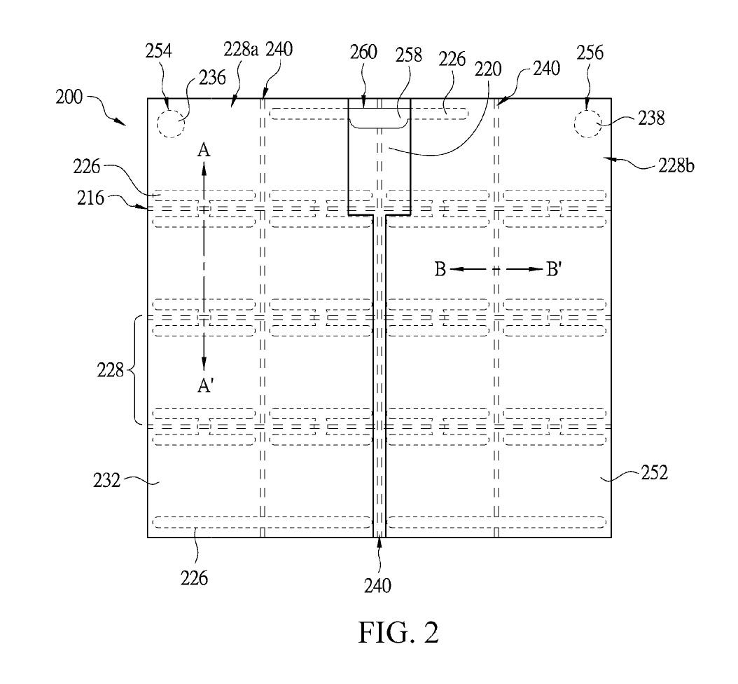

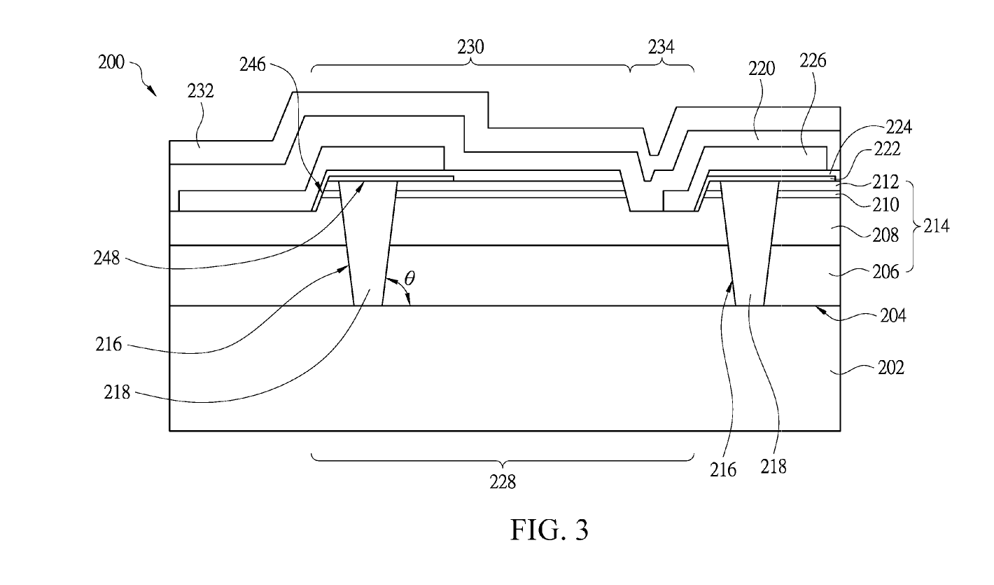

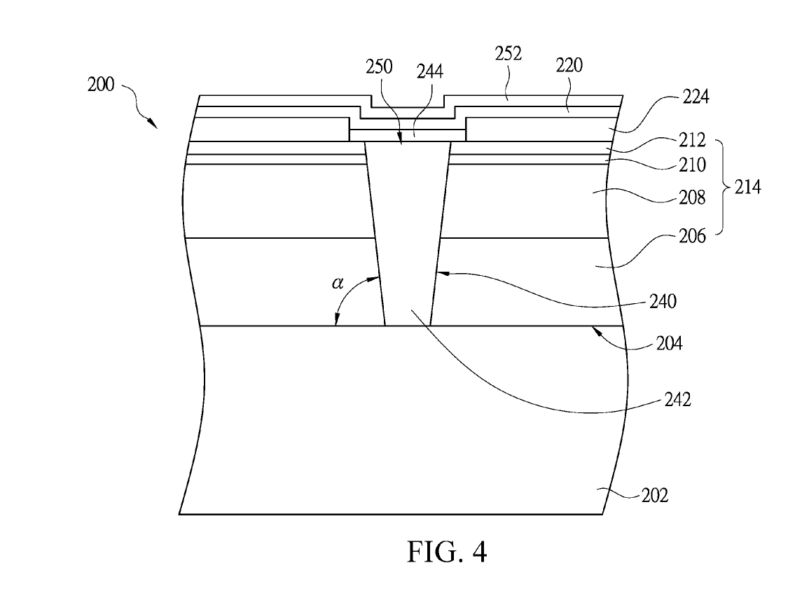

Referring to FIGS. 2-4, FIG. 2 is a schematic top view of an LED structure according to an embodiment of the present invention, FIG. 3 is a sectional view of an LED structure along a sectional line AA′ in FIG. 2, and FIG. 4 is a sectional view of an LED structure along a sectional line BB′ in FIG. 2. In this embodiment, the LED structure 200 is, for example, a high voltage LED (HV LED).

The LED structure 200 is formed by connecting a plurality of LED chips 228 in series. In the exemplary embodiment shown in FIG. 2, the LED structure 200 is formed of 16 LED chips 228. Isolation trenches 216 in a first direction and isolation trenches 240 in a second direction are disposed around each LED chip 228 to electrically isolation any two adjacent LED chips 228. In addition, the adjacent LED chips 228 are electrically connected through a conductive interconnection layer 226, so as to connect all LED chips 228 in series.

Referring to FIGS. 2 and 3, the LED structure 200 includes an insulation substrate 202, a plurality of LED chips 228, a plurality of interconnection layers 226, a first conductive type electrode pad 238, a second conductive type electrode pad 236, a reflective insulating layer 220, a first conductive type bonding pad 252, and a second conductive type bonding pad 232. The material of the insulation substrate 202 is, for example, sapphire. In some examples, the insulation substrate 202 is, for example, a patterned sapphire substrate (PSS), that is, a plurality of patterned structures (not shown) is formed on the surface 204 of the insulation substrate 202. By disposing these patterned structures, the light extraction efficiency of the LED chip 228 is enhanced.

These LED chips 228 are disposed on the surface 204 of the insulation substrate 202. Each LED chip 228 includes an epitaxial layer 214. In the embodiment shown in FIG. 3, the epitaxial layer 214 includes an undoped semiconductor layer 206, a first conductivity type semiconductor layer 208, an active layer 210, and a second conductivity type semiconductor layer 212 that are grown and stacked sequentially on the surface 204 of the insulation substrate 202. In certain embodiment, the first electrical type and the second electrical type are opposite. For example, one of the first electrical type and the second electrical type is n type, and the other is p type. In another embodiment, the epitaxial layer 214, for example, does not include the undoped semiconductor layer 206.

In certain embodiments, the active layer 210 is, for example, a multiple Quantum Well (MQW) structure formed of multiple groups of quantum wells and barrier layers stacked to each other alternately. In certain embodiments, the materials of the undoped semiconductor layer 206, the first conductivity type semiconductor layer 208, the active layer 210, and the second conductivity type semiconductor layer 212 are, for example, gallium nitride series materials.

Each LED chip 228 includes a mesa structure 230 and an exposed portion 234 adjacent to each other. The mesa structure 230 includes a portion of the undoped semiconductor layer 206, a portion of the first conductivity type semiconductor layer 208, a portion of the active layer 210, and a portion of the second conductivity type semiconductor layer 212. When defining the mesa structure 230 in the epitaxial layer 214, the exposed portion 234 is formed by removing a portion of the second conductivity type semiconductor layer 212, a portion of the active layer 210, and even a portion of the first conductivity type semiconductor layer 208 below, so as to expose portion of the first conductivity type semiconductor layer 208. Therefore, the exposed portion 234 is the exposed portion of the first semiconductor layer 208, and the exposed portion 234 includes a portion of the undoped semiconductor layer 206 and a portion of the first conductivity type semiconductor layer 208, but do not include the active layer 210 and the second conductivity type semiconductor layer 212.

In an embodiment, as shown in FIG. 3, the sectional shape of the mesa structure 230 is, for example, trapezoidal, and the mesa structure 230 has an inclined side surface 246. The mesa structure 230 is provided with the inclined side surface 246, which facilitate the subsequent deposition of the interconnection layer 226. Alternatively, in another embodiment, the sectional shape of the mesa structure 230 is, for example, rectangular, and the mesa structure 230 has a vertical side surface 246.

Each LED chip 228 further includes an isolation trench 216. In an LED chip 228, the isolation trench 216 is disposed in the mesa structure 230, and is preferably near the exposed portion 234 of the adjacent LED chip 228. In the mesa structure 230, the isolation trench 216 extends downwardly from the second conductivity type semiconductor layer 212 to the undoped semiconductor layer 206. In an embodiment, the bottom of the isolation trench 216 is located in the undoped semiconductor layer 206. In the embodiment shown in FIG. 3, the bottom of the isolation trench 216 directly extends to the surface 204 of the insulation substrate 202, so as to expose the surface 204 of the insulation substrate 202. In the embodiment where the epitaxial structure 214 does not include the undoped semiconductor layer 206, the isolation trench 216 extends from the second conductivity type semiconductor layer 212 towards the surface 204 of the insulation substrate 202. Therefore, the bottom of the isolation trench 216 in the embodiment exposes a portion of the surface 204 of the insulation substrate 202.

In some embodiments, each LED chip 228 may further include an insulating layer 218. In the LED chip 228, the insulating layer 218 is filled in the isolation trench 216, covers the surface 204 of the insulation substrate 202, and preferably seals the opening 248 of the isolation trench 216. As shown in FIG. 3, the insulating layer 218 can completely fill the isolation trench 216. Alternatively, in another embodiment, the insulating layer 218 does not completely fill the isolation trench 216. For example, the insulating layer 218 of the isolation trench 216 can have a hole. In some further embodiments, the insulating layer 218, for example, only fills a part of depth of the isolation trench 216.

In an embodiment, as shown in FIG. 3, the sectional shape of the isolation trench 216 is invertedly trapezoidal, so as to facilitate the deposition of the insulating layer 218 in the isolation trench 216. An included angle θ between the isolation trench 216 and the surface 204 of the insulation substrate 202 is, for example, from 30° to 90°. In another embodiment, the sectional shape of the isolation trench 216 can also be, for example, rectangular. In addition, the material of the insulating layer 218 is, for example, a silicon dioxide or silicon nitride (SiNₓ).

In an embodiment, each LED chip 228 also selectively includes a current blocking layer 222, so as to disperse the current distribution. As shown in FIG. 3, the current blocking layer 222 is disposed on the mesa structure 230, is located above the isolation trench 216, and covers the insulating layer 218, a portion of the second conductivity type semiconductor layer 212, and the side surface 246 of the mesa structure 230 where the interconnection layer 226 is located.

Each LED chip 228 further selectively includes a transparent conductive layer 224. The material of the transparent conductive layer 224 is, for example, an indium tin oxide (ITO). The transparent conductive layer 224 is disposed on the mesa structure 230, covers the current blocking layer 222, and extends on the second conductivity type semiconductor layer 212 of the mesa structure 230. Alternatively, the transparent conductive layer 224 is only located on the second conductivity type semiconductor layer 212 of the mesa structure 230, but does not cover the current blocking layer 222, in which the interconnection layer 226 extends to cover a portion of the transparent conductive layer 224, so as to facilitate electrical conduction.

In an LED structure 200, the interconnection layer 226 connects adjacent LED chips 228, respectively, so as to electrically connect these LED chips 228 in series. The interconnection layer 226 extends from the exposed portion 234 of the first conductivity type semiconductor layer 208 of one LED chip 228 of the two adjacent LED chips 228 to the transparent conductive layer 224 of the mesa structure 230 of another LED chip 228. As shown in FIG. 3, the interconnection layer 226 directly extends from the exposed portion 234 of one LED chip 228 of two adjacent LED chips 228 to the current blocking layer 222 of the side surface 246 of the mesa structure 230 of another LED chip 228, and is then connected to the transparent conductive layer 224 located above the mesa structure 230 along the side surface 246 of the mesa structure 230. Therefore, the lowermost surface of the interconnection layer 226 is located on the exposed portion 234 of the first conductivity type semiconductor layer 208, and contacts the exposed portion 234 of the first conductivity type semiconductor layer 208. The material of the interconnection layer 226 is a conductive material, for example, a metal. In an embodiment, the interconnection layer 226 is, for example, a chromium/platinum/gold (Cr/Pt/Au) stacked structure formed by sequentially stacking a chromium layer, a platinum layer, and a gold layer.

As shown in FIG. 3, the portion of the interconnection layer 226 on the mesa structure 230 covers the current blocking layer 222 and the transparent conductive layer 224 above the isolation trench 216. Therefore, the current blocking layer 222 is between the interconnection layer 226 above the mesa structure 230 and the insulating layer 218 in the isolation trench 216, and the transparent conductive layer 224 is between the interconnection layer 226 and the current blocking layer 222 above the mesa structure 230.

In an embodiment, a portion of the current blocking layer 222 extends horizontally to the outside of the interconnection layer 226, so as to achieve a better current blocking effect, and preventing a large amount of current from directly flowing downwardly from the interconnection layer 226 into the LED chip 228 to cause a current crowding situation, and further the current is forced to flow from the transparent conductive layer 224 into the mesa structure 230. Accordingly, the light emission efficiency of the LED chip 228 can be significantly enhanced. Therefore, in a preferred embodiment, the transparent conductive layer 224 extends on the second conductivity type semiconductor layer 212 on the mesa structure 230.

Referring to FIG. 2 and FIG. 3 again, the first conductive type electrode pad 238 and the second conductive type electrode pad 236 are disposed on the two LED chips of the LED structure 200, respectively. For example, the two LED chips are a starting chip and an end chip of an LED chip array, respectively, that is, the LED chips 228a and 228b. The first conductive type electrode pad 238 and the second conductive type electrode pad 236 can be fabricated at the same time with the interconnection layer 226, and the materials of the first conductive type electrode pad 238 and the second conductive type electrode pad 236 may also be the same as the material of the interconnection layer 226. The materials of the first conductive type electrode pad 238 and the second conductive type electrode pad 236 are a conductive material, for example, a metal. In an embodiment, the first conductive type electrode pad 238 and the second conductive type electrode pad 236 are both, for example, a chromium/platinum/gold stacked structure formed by sequentially stacking a chromium layer, a platinum layer, and a gold layer. In an LED structure 200, the first conductive type electrode pad 238 is located on the exposed portion 234 of the first conductivity type semiconductor layer 208 of the LED chip 228a, and is electrically connected to the exposed portion 234 of the first conductivity type semiconductor layer 208. On the other hand, the second conductive type electrode pad 236 is, for example, located on the transparent conductive layer 224 or the second conductivity type semiconductor layer 212 on the mesa structure 230 of the LED chip 228b, and is electrically connected to the second conductivity type semiconductor layer 212.

In an embodiment, the LED structure 200 may further include a test pad 258. The test pad 258 can be, according to a process or production demand, disposed on one or more required LED chips 228. In the embodiment shown in FIG. 2, the test pad 258 extends and is disposed within two adjacent LED chips 228 of two adjacent columns of LED chips. That is, the test pad 258 is located on the two LED chips 228 between the LED chips 228a and 228b, and is connected to the interconnection layer 226 of these two adjacent LED chips 228.

The reflective insulating layer 220 covers the interconnection layer 226, the mesa structure 230, the exposed portion 234 of the first conductivity type semiconductor layer 212, the first conductive type electrode pad 238, and the second conductive type electrode pad 236 of the LED chip 228. The reflective insulating layer 220 is, for example, a DBR. In this embodiment, the DBR material, for example, includes a repetitive stack layers of a silicon dioxide/titanium dioxide (SiO₂/TiO₂) or silicon dioxide/silicon nitride (SiO₂/SiNₓ), or a combination thereof. In an embodiment, the reflective insulating layer 220 is at least disposed with penetration holes 256 and 254, in which the two penetration holes 256 and 254 expose a portion of the first conductive type electrode pad 238 and a portion of the second conductive type electrode pad 236, respectively. In such a manner, the first conductive type bonding pad 252 and the second conductive type bonding pad 232 formed subsequently are electrically connected to the exposed first conductive type electrode pad 238 and second conductive type electrode pad 236, through the penetration holes 256 and 254, respectively.

In another embodiment, the reflective insulating layer 220 is further, according to the disposed test pad 258, disposed with a penetration hole 260 correspondingly. The penetration hole 260 exposes a portion of the test pad 258, so as to facilitate the subsequent detection of the LED structure 200 through the penetration hole 260 via the exposed test pad 258.

As shown in FIG. 2, the first conductive type bonding pad 252 and the second conductive type bonding pad 232 are located on the reflective insulating layer 220, respectively, so as to form two separated parts. That is to say, the first conductive type bonding pad 252 and the second conductive type bonding pad 232 are separated from each other. The first conductive type bonding pad 252 further contacts and is electrically connected to the exposed first conductive type electrode pad 238 through the penetration hole 256 of the reflective insulating layer 220. On the other hand, the second conductive type bonding pad 232 further contacts and is electrically connected to the exposed second conductive type electrode pad 236 through another penetration hole 254 of the reflective insulating layer 220.

Referring to FIGS. 2 and 4, each LED chip 228 further includes another isolation trench 240. The isolation trench 240 is disposed in the epitaxial layer 214 outside the mesa structure 230, and abuts the isolation trench 216. As shown in FIG. 2, the isolation trench 240 electrically isolates two adjacent columns of the LED chips 228. Also, different from the isolation trench 216, conductive materials such as a transparent conductive layer or an interconnection layer do not cover the isolation trench 240.

The isolation trench 240 extends from the second conductivity type semiconductor layer 212 of the epitaxial layer 214 to the undoped semiconductor layer 206. Therefore, the bottom of the isolation trench 240 is located in the undoped semiconductor layer 206. In the embodiment shown in FIG. 4, the bottom of the isolation trench 240 directly extends to the surface 204 of the insulation substrate 202 and exposes the surface 204 of the insulation substrate 202. In the embodiment where the epitaxial layer 214 does not include the undoped semiconductor layer 206, the isolation trench 240 extends from the second conductivity type semiconductor layer 212 towards the surface 204 of the insulation substrate 202, and at this time the bottom of the isolation trench 240 exposes a portion of the surface 204 of the insulation substrate 202.

In some embodiments, each LED chip 228 further includes another insulating layer 242. The insulating layer 242 is filled in the isolation trench 240 and preferably seals the opening 250 of the isolation trench 240. In an example, the insulating layer 242 completely fills the isolation trench 240. Alternatively, in another example, the insulating layer 242 does not completely fill the isolation trench 240. In addition, as shown in FIG. 4, the sectional shape of the isolation trench 240 is, for example, invertedly trapezoidal, so as to facilitate the deposition of the insulating layer 242 in the isolation trench 240. In an exemplary example, an included angle α between the isolation trench 240 and the surface 204 of the insulation substrate 202 is, for example, from 30° to 90°. Alternatively, in another example, the sectional shape of the isolation trench 240 can also be, for example, rectangular. The material of the insulating layer 242 is, for example, a silicon dioxide or silicon nitride.

In an embodiment, each LED chip 228 also selectively includes another current blocking layer 244. As shown in FIG. 4, the current blocking layer 244 is located above the isolation trench 240, and covers the insulating layer 242 inside the isolation trench 240, and the second conductivity type semiconductor layer 212 on the periphery of the opening 250 of the isolation trench 240. The reflective insulating layer 220 also covers the current blocking layer 244 above the isolation trench 240.

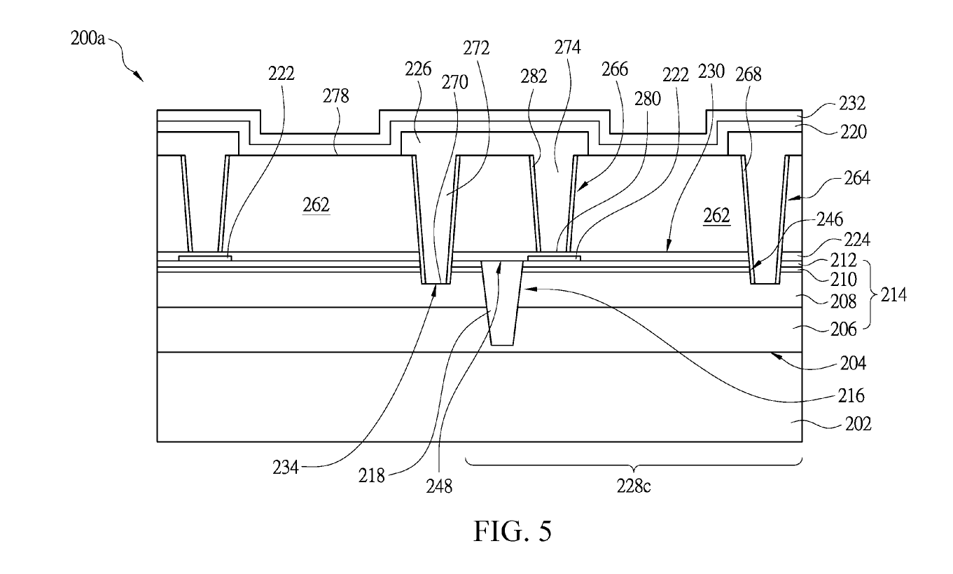

FIG. 5 is a sectional view of an LED structure according to another embodiment of the present invention. The architecture of the LED structure 200a in the embodiment is approximately the same as the LED structure 200 in the above embodiment, and the main difference between the two lies in that each LED chip 228c of the LED structure 200a further includes a dielectric layer 262.

In the LED structure 200a, the dielectric layer 262 is stacked on the epitaxial layer 214. The dielectric layer 262 is also referred to as an interlayer dielectric (ILD) layer. The material of the dielectric layer 262 is an insulating material such as a silicon dioxide and silicon nitride. Each LED chip 228c has a first electrical contact hole 264 and a second electrical contact hole 266. The first electrical contact hole 264 and the second electrical contact hole 266 both penetrate the dielectric layer 262. The first electrical contact hole 264 extends from the upper surface 278 of the dielectric layer 262 to the first conductivity type semiconductor layer 208 of the epitaxial layer 214. Therefore, the bottom 270 of the first electrical contact hole 264 exposes a portion of the first conductivity type semiconductor layer 208.

In the embodiment where the LED chip 228c does not have a transparent conductive layer, the second electrical contact hole 266 extends from the upper surface 278 of the dielectric layer 262 to the second conductivity type semiconductor layer 212 of the epitaxial layer 214. That is, the bottom 280 of the second electrical contact hole 266 exposes a portion of the second conductivity type semiconductor layer 212. Also, in the embodiment where the LED chip 228c has a transparent conductive layer 224, the transparent conductive layer 224 is between the dielectric layer 262 and the epitaxial layer 214, and the second electrical contact hole 266 only extends from the upper surface 278 of the dielectric layer 262 to the transparent conductive layer 224. Therefore, the bottom 280 of the second electrical contact hole 266 exposes a portion of the transparent conductive layer 224. In each LED chip 228c, the isolation trench 216 is between the second electrical contact hole 266 of the LED chip 228c and the first electrical contact hole 264 of the adjacent LED chip 228c.

Each LED chip 228c further includes an insulating lining layer 268. The insulating lining layer 268 covers the sidewall of the first electrical contact hole 264, so as to electrically isolate the interconnection layer 226 subsequently filled in the first electrical contact hole 264, from the transparent conductive layer 224, the second conductivity type semiconductor layer 212, the active layer 210, and the first conductivity type semiconductor layer 208 that are exposed by the sidewall of the first electrical contact hole 264. Therefore, it can be avoided that the current inside the first electrical contact hole 264 flows through the transparent conductive layer 224 with a relatively small resistance to reach the second electrical contact hole 266, which further causes a short circuit and makes light emission impossible. By disposing the insulating lining layer 268, direct conductive connection between the first conductivity type semiconductor layer 208 and the second conductivity type semiconductor layer 212 from the same LED chip or adjacent LED chips 228c through the transparent conductive layer 224 can be avoided.

Each LED chip 228c may further include an insulating lining layer 282. The insulating lining layer 282 covers the sidewall of the second electrical contact hole 266, so as to enhance the electrical reliability of the LED chip 228c. However, the LED chip 228c, for example, can only include the insulating lining layer 268, and does not include the insulating lining layer 282. The materials of the insulating lining layers 268 and 282 are, for example, silicon dioxides or silicon nitrides.

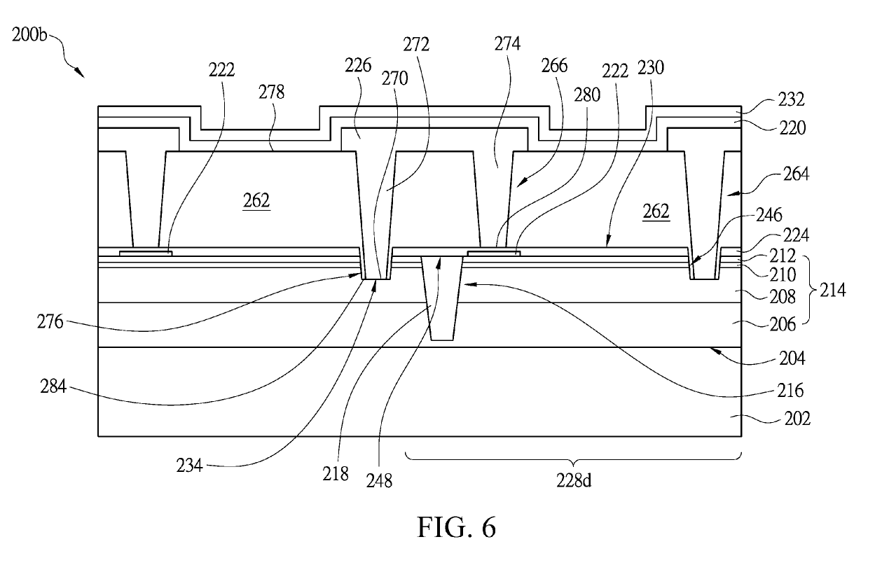

In another embodiment, the LED structure also does not include an insulating lining layer. FIG. 6 is a sectional view of an LED structure according to a further embodiment of the present invention. In this embodiment, the architecture of the LED structure 200b is approximately the same as the architecture of the LED structure 200a in the above embodiment, and the difference between the two lies in that an insulating lining layer is not disposed inside the first electrical contact hole 264 and the second electrical contact hole 266 of the LED chip 228d of the LED structure 200b.

In the LED structure 200b, the epitaxial layer 214 of each LED chip 228d is disposed with a groove 276. The groove 276 extends from the second conductivity type semiconductor layer 212 of the epitaxial layer 214 towards the first conductivity type semiconductor layer 208. The bottom 284 of the groove 276 is located in the first conductivity type semiconductor layer 208. That is, the bottom 284 of the groove 276 exposes the first conductivity type semiconductor layer 208. The first electrical contact hole 264 is connected to the groove 276. Further, a portion of the dielectric layer 262 covers the sidewall of the groove 276, and the bottom 270 of the first electrical contact hole 264 exposes a portion of the bottom 284 of the groove 276.

By the design of making the dielectric layer 262 extend to cover the sidewall of the groove 276 of the epitaxial layer 214, the LED structure 200b does not require to otherwise dispose the insulating lining layer on the sidewall of the first electrical contact hole 264, thereby achieving the effect of electrically insulating the interconnection layer 226 from the epitaxial layer 214 and the transparent conductive layer 224 exposed from the sidewall of the groove 276.

Referring to FIG. 5 again, in the LED structure 200a, the interconnection layers 226 are respectively filled in the second electrical contact hole 266 of the LED chip 228c, and extends to be filled in the first electrical contact hole 264 of the adjacent LED chip 228c through the upper surface 278 of the dielectric layer 262 above the isolation trench 216. The portion of the interconnection layer 226 filled in the first electrical contact hole 264 and the second electrical contact hole 266 are also referred to as contact plugs 272 and 274, respectively. The reflective insulating layer 220 covers the dielectric layer 262 and the interconnection layer 226.

As shown in FIG. 5, in each LED chip 228c, the current blocking layer 222 is disposed on a portion of the epitaxial layer 214, and is located below the bottom 280 of the second electrical contact hole 266. Therefore, the current blocking layer 222 is between the bottom 280 of the second electrical contact hole 266 and the epitaxial layer 214. Also, the transparent conductive layer 224 covers the current blocking layer 222.

By disposing the current blocking layer 222, it can be avoided that a large amount of current directly flows downwardly into the LED chip 228c through the contact plug 274 of the interconnection layer 226, which results in a current crowding situation, and further forces the current to flow into epitaxial layer 214 through the transparent conductive layer 224. In an embodiment, the current blocking layer 222 is preferably larger than the area of the bottom of the contact plug 274. That is, the area of the current blocking layer 222 preferably covers the entire bottom of the contact plug 274, so as to achieve a better current blocking effect.

In another embodiment, the insulating layer 218 can only fill a part of the depth of the isolation trench 216, and the upper surface of the insulating layer 218 and the epitaxial layer 214 are not required to be made at the same height. In the embodiment, the current blocking layer 222, for example, extends from below the bottom 280 of the second electrical contact hole 266 to the opening 248 of the nearby insulating trench 216, and the current blocking layer 222 covers the opening 248 of the insulating trench 216. By disposing the current blocking layer 222, the insulating effect may be further increased, so as to prevent the transparent conductive layer 224 from covering the epitaxial layer 214 that exposed by the insulating trench to cause a short circuit.

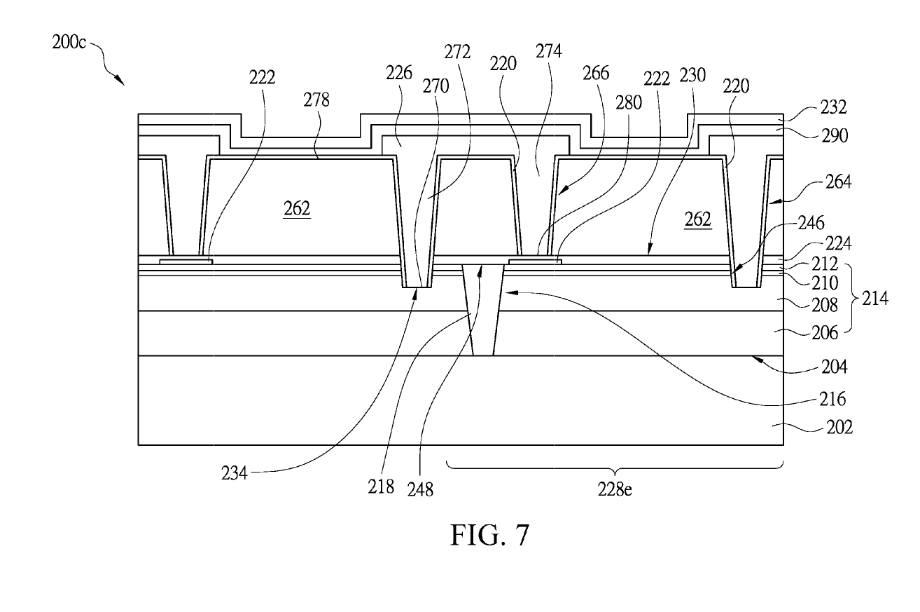

FIG. 7 is a sectional view of an LED structure according to yet a further embodiment of the present invention. In this embodiment, the architecture of the LED structure 200c is approximately the same the architecture of the LED structure 200a in the above embodiment, and the difference between the two lies in that the reflective insulating layer 220 of the LED structure 200c replaces the insulating lining layers 268 and 282 of the LED structure 200a. Further, the reflective insulating layer 220 covers the sidewall of the first electrical contact hole 264 of the LED chip 228e, the sidewall of the second electrical contact hole 266, and the upper surface 278 of the dielectric layer 262. In addition, the LED structure 200c further includes an insulating layer 290. The insulating layer 290 covers the interconnection layer 226 and the reflective insulating layer 220.

Referring to FIG. 2 together, in the LED structure 200c, the insulating layer 290 is at least disposed with two penetration holes like the reflective insulating layer 220 in the LED structure 200, in which the two penetration hole exposes a portion of the first conductive type electrode pad 238 and a portion of the second conductive type electrode pad 236, respectively. In such a manner, the first conductive type bonding pad 252 and the second conductive type bonding pad 232 formed subsequently are electrically connected to the exposed first conductive type electrode pad 238 and second conductive type electrode pad 236, respectively, through the two penetration holes.

In another embodiment, the insulating layer 290 can further, according to the test pad 258 being disposed, be correspondingly provided with another penetration hole. The penetration hole exposes a portion of the test pad 258, so as to facilitate the subsequent detection of the LED structure 200c through the penetration hole via the exposed test pad 258.

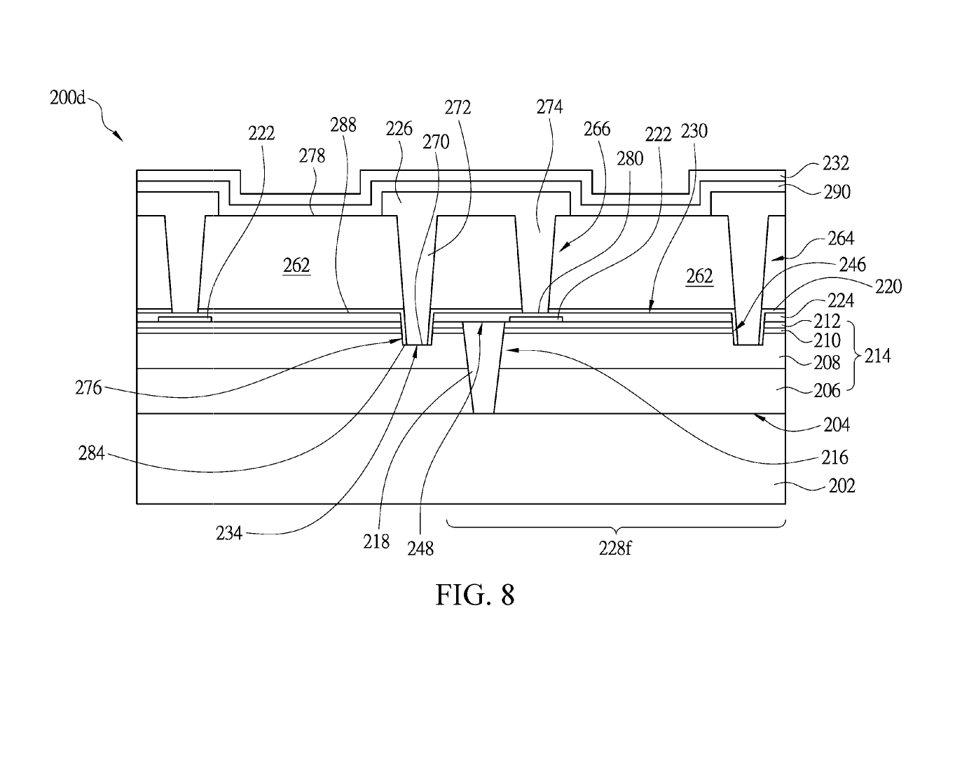

FIG. 8 is a sectional view of an LED structure according to yet a further embodiment of the present invention. In this embodiment, the architecture of the LED structure 200d is approximately the same as the architecture of the LED structure 200b in the above embodiment, and the difference between the two lies in that the reflective insulating layer 220 of each LED chip 228f of the LED structure 200d covers the sidewall of the groove 276 of the epitaxial layer 214 and the upper surface 288 of the transparent conductive layer 224. In addition, the LED structure 200d further includes an insulating layer 290. The insulating layer 290 covers the interconnection layer 226 and the upper surface 278 of the dielectric layer 262.

In the LED structure 200d in the embodiment, because the position that the reflective insulating layer 220 is disposed is relatively close to the active layer 210, so that light rays emitted by the active layer 210 do not pass through the dielectric layer 262. Therefore, the loss that light rays are absorbed by the dielectric layer 262 is reduced, and the light emission efficiency of the LED structure 200d can be further enhanced.

Referring to FIG. 2 together, in an LED structure 200d, an insulating layer 290 can be, like the reflective insulating layer 220 of the LED structure 200, at least disposed with two penetration holes, in which the two penetration holes expose a portion of the first conductive type electrode pad 238 and a portion of the second conductive type electrode pad 236, respectively. Therefore, the first conductive type bonding pad 252 and the second conductive type bonding pad 232 formed subsequently are electrically connected to the exposed first conductive type electrode pad 238 and second conductive type electrode pad 236, respectively, through the two penetration holes.

In another embodiment, the insulating layer 290 can further, according to the test pad 258 being disposed, be correspondingly provided with another penetration hole. The penetration hole, for example, exposes a portion of the test pad 258, so as to facilitate the subsequent detection of the LED structure 200d through the penetration hole via the exposed test pad 258.

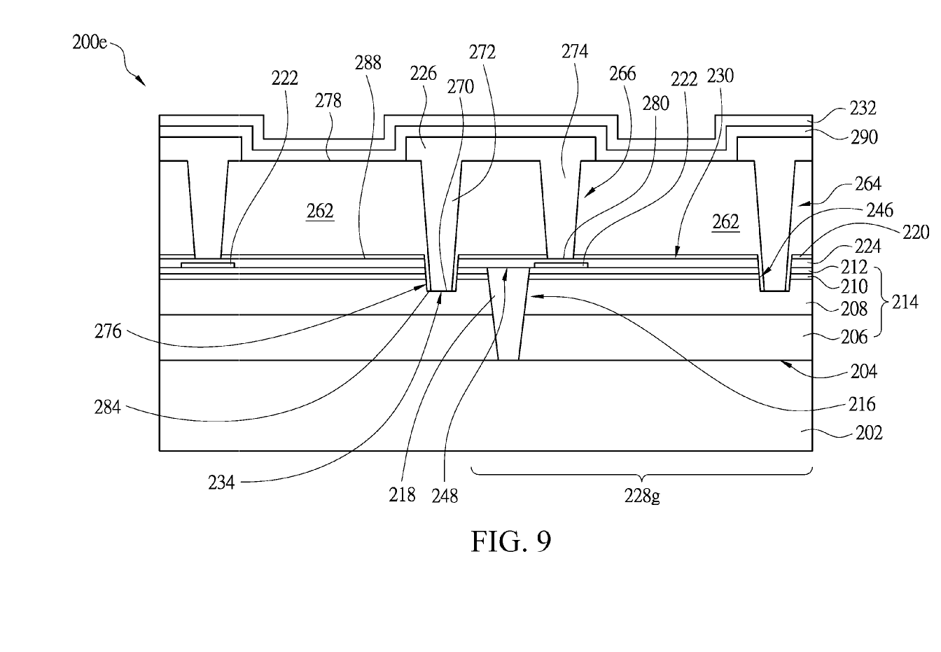

FIG. 9 is a sectional view of an LED structure according to yet a further embodiment of the present invention. In this embodiment, the architecture of the LED structure 200e is approximately the same as the architecture of the LED structure 200b in the above embodiment, and the difference between the two lies in that the reflective insulating layer 220 of each LED chip 228g of the LED structure 200e covers the upper surface 288 of the transparent conductive layer 224. In addition, the LED structure 200e further includes an insulating layer 290. The insulating layer 290 covers the interconnection layer 226 and the upper surface 278 of the dielectric layer 262.

Referring to FIG. 2 together, in the LED structure 200e, the insulating layer 290 can be, like the reflective insulating layer 220 of the LED structure 200, at least provided with two penetration holes, in which the two penetration holes expose a portion of the first conductive type electrode pad 238 and a portion of the second conductive type electrode pad 236, respectively. In such a manner, the first conductive type bonding pad 252 and the second conductive type bonding pad 232 formed subsequently are electrically connected to the exposed first conductive type electrode pad 238 and second conductive type electrode pad 236, respectively, through the two penetration holes.

In another embodiment, the insulating layer 290 can further, according to the test pad 258 being disposed, be correspondingly provided with another penetration hole. The penetration hole exposes a portion of the test pad 258, so as to facilitate the subsequent detection of the LED structure 200e through the penetration hole via the exposed test pad 258.

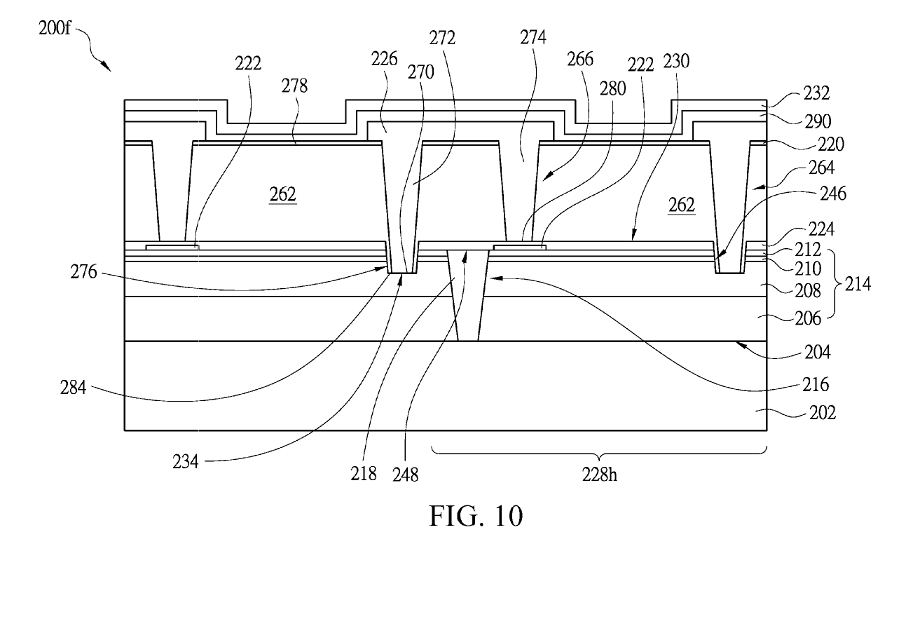

FIG. 10 is a sectional view of an LED structure according to yet a further embodiment of the present invention. In this embodiment, the architecture of the LED structure 200f is approximately the same as the architecture of the LED structure 200b in the above embodiment, and the difference between the two lies in that the reflective insulating layer 220 of each LED chip 228h of the LED structure 200f covers the upper surface 278 of the dielectric layer 262. In addition, the LED structure 200f further includes an insulating layer 290. The insulating layer 290 covers the interconnection layer 226 and the reflective insulating layer 220.

Referring to FIG. 2 together, in the LED structure 200f, the insulating layer 290 can be, like the reflective insulating layer 220 of the LED structure 200, at least provided with two penetration holes, in which the two penetration holes expose a portion of the first conductive type electrode pad 238 and a portion of the second conductive type electrode pad 236, respectively. In such a manner, the first conductive type bonding pad 252 and the second conductive type bonding pad 232 formed subsequently are electrically connected to the exposed first conductive type electrode pad 238 and second conductive type electrode pad 236, respectively, through the two penetration holes.

In another embodiment, the insulating layer 290 can further, according to the test pad 258 being disposed, be correspondingly provided with another penetration hole. The penetration hole exposes a portion of the test pad 258, so as to facilitate the subsequent detection of the LED structure 200f through the penetration hole via the exposed test pad 258.

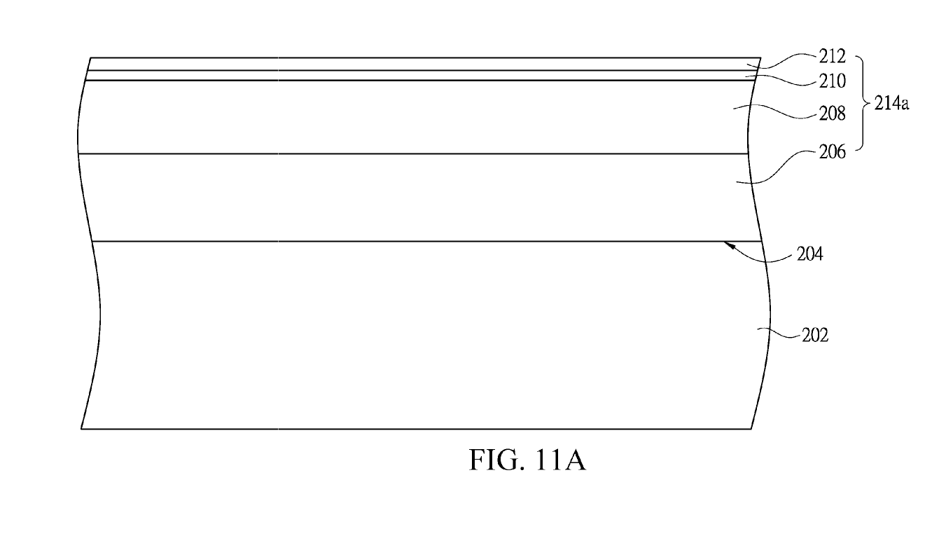

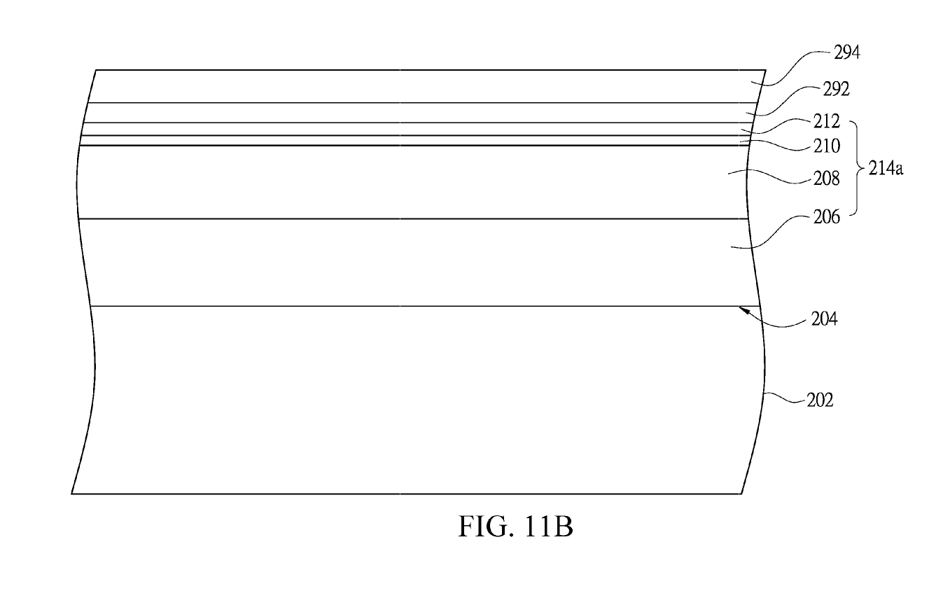

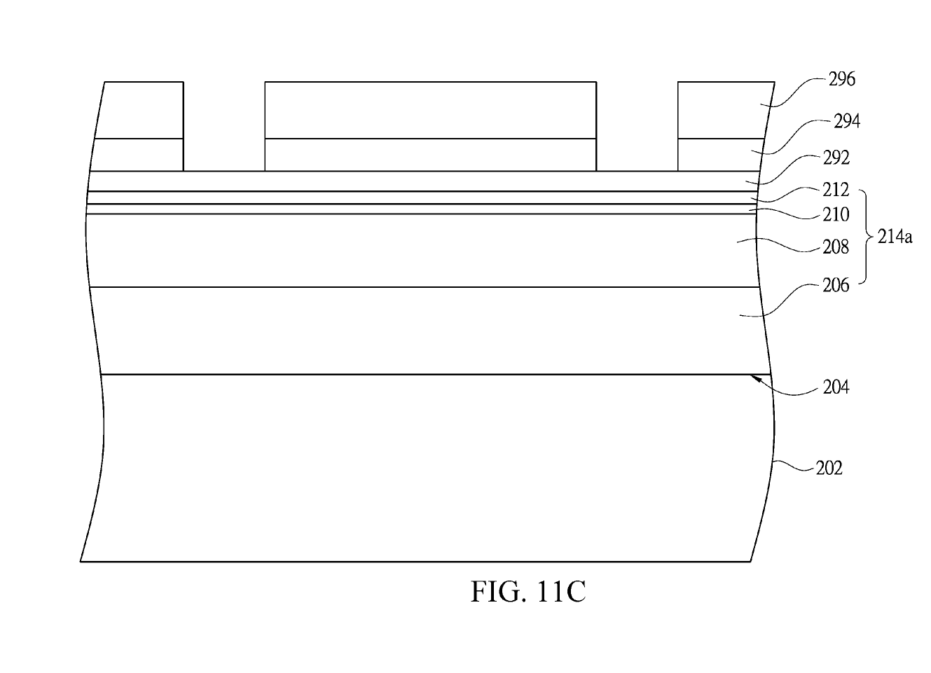

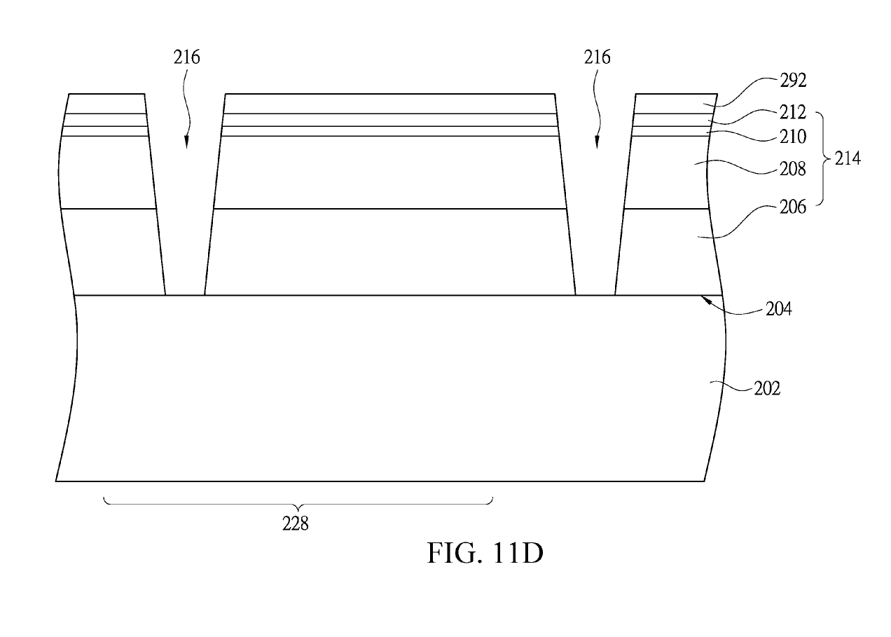

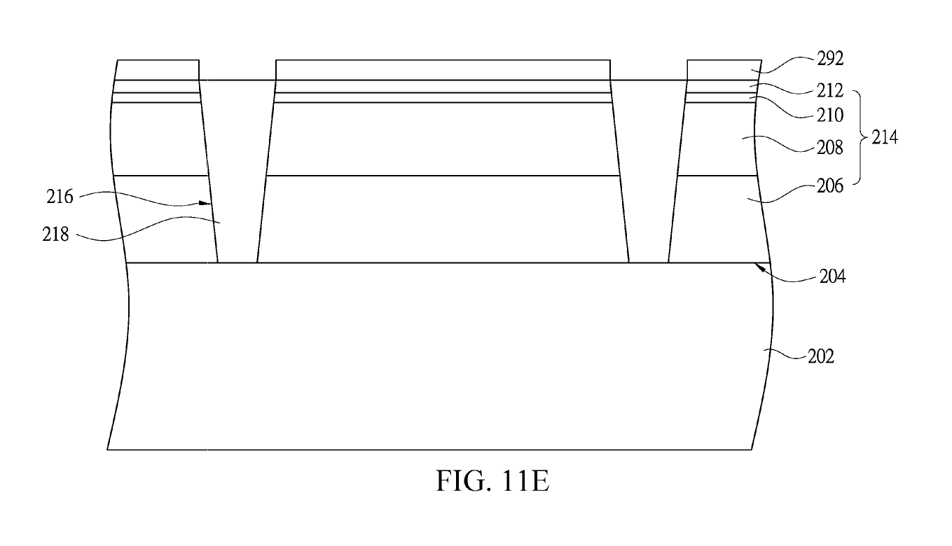

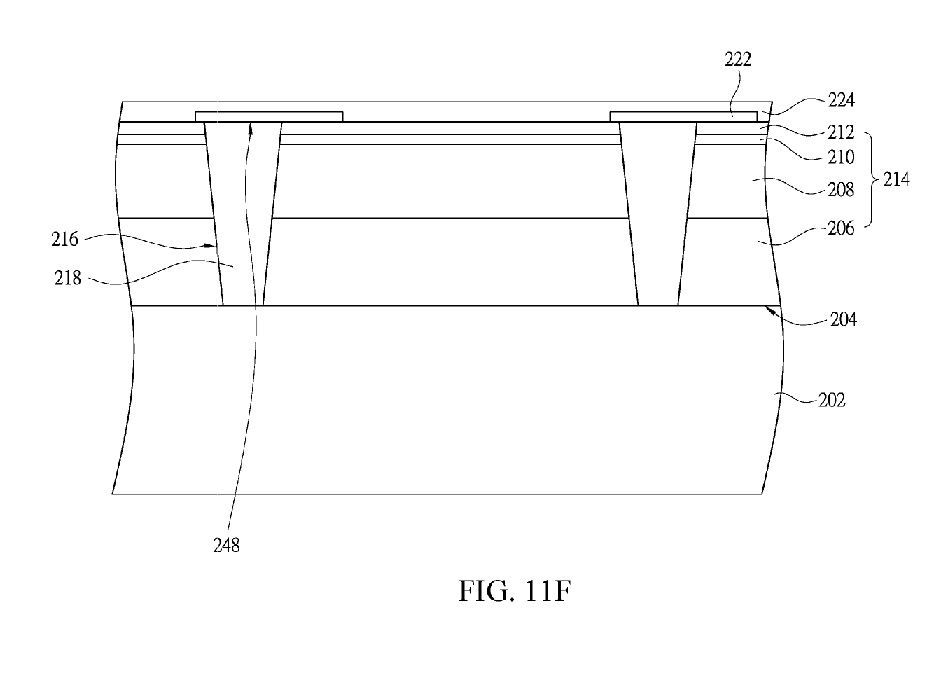

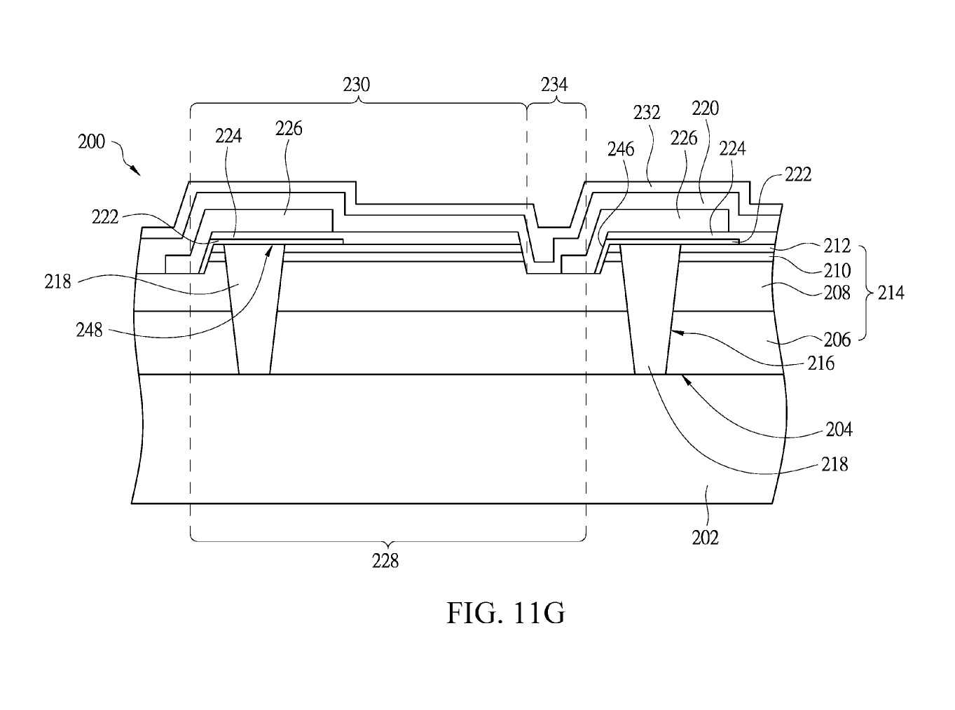

Referring to FIGS. 11A-11G, which is a process sectional view of an LED structure according to an embodiment of the present invention. In the embodiment, when manufacturing the LED structure 200, an insulation substrate 202 is provided first. Then, an undoped semiconductor layer 206, a first conductivity type semiconductor layer 208, an active layer 210, and a second conductivity type semiconductor layer 212 are sequentially formed on the surface 204 of the insulation substrate 202 in an epitaxial growth manner, for example, in a metalorganic vapour phase epitaxy (MOCVD) manner. As shown in FIG. 11A, the undoped semiconductor layer 206, the first conductivity type semiconductor layer 208, the active layer 210, and the second conductivity type semiconductor layer 212 are sequentially stacked to form an epitaxial structure 214a. In another embodiment, the epitaxial structure 214a does not include the undoped semiconductor layer 206.

Next, for example, in a deposition manner, an etching stop layer 292 is formed covering the second conductivity type semiconductor layer 212. The material of the etching stop layer 292 can be, for example, silicon nitride (SiNₓ). As shown in FIG. 11B, for example, in a deposition manner, a hard mask layer 294 is then formed covering the etching stop layer 292. The material of the hard mask layer 294 is, for example, a nickel or silicon dioxide. The etching stop layer 292 can serve as the etching end in defining the pattern of the hard mask layer 294.

Subsequently, for example, in a coating manner, a photoresist layer 296 is first formed covering the hard mask layer 294. Then, for example, in a lithography process, the pattern of the photoresist layer 296 is defined to remove a portion of the photoresist layer 296 to expose a portion of the hard mask layer 294, so as to define predetermined positions and shapes of the isolation trenches 216 and 240 in the photoresist layer 296. Next, for example, in an etching manner, the patterned photoresist layer 296 is taken as an etching mask, and the etching stop layer 292 serve as the etching end, so as to remove the exposed portion of the hard mask layer 294, and transfer the pattern in the photoresist layer 296 into the hard mask layer 294. In such a manner, the predetermined positions and shapes of the isolation trenches 216 and 240 that are originally defined in the photoresist layer 296 are transferred to the hard mask layer 294, as shown in FIG. 11C.

Subsequently, for example, in an inductively coupled plasma etching (ICP) manner, and by using the patterned photoresist layer 296 and hard mask layer 294 as etching masks, the epitaxial structure 214a is etched to remove a portion of the second conductivity type semiconductor layer 212, a portion of the active layer 210, a portion of the first conductivity type semiconductor layer 208, and a portion of the undoped semiconductor layer 206, so as to transfer the pattern in the hard mask layer 294 into the epitaxial structure 214a, while a plurality of isolation trenches 216 and 240 is formed in the epitaxial structure 214a. As shown in FIG. 2 and FIG. 11D, the isolation trenches 216 respectively neighboring the isolation trenches 240, and the isolation trenches 216 and 240 define the epitaxial structure 214a into epitaxial layers 214 of a plurality of LED chips 228. Each LED chip 228 includes an isolation trench 216, and the isolation trench 240 is disposed between the LED chips 228 of two adjacent columns.

In an embodiment, as shown in FIG. 4 and FIG. 11D, the bottom of the isolation trench 216 and the bottom of the isolation trench 240 both exposes a portion of the surface 204 of the insulation substrate 202. In another embodiment, the bottom of the isolation trench 216 and the bottom of the isolation trench 240 are located in the undoped semiconductor layer 206. In the embodiment where the epitaxial layer 214 does not include the undoped semiconductor layer 206, the isolation trenches 216 and 240 extend from the second conductivity type semiconductor layer 212 towards the surface 204 of the insulation substrate 202, and the isolation trenches 216 and 240 both exposed a portion of the surface 204 of the insulation substrate 202.

In an embodiment, as shown in FIG. 11D, after the isolation trenches 216 and 240 are formed, the residual photoresist layer 296 and hard mask layer 294 can be removed, so as to expose the etching stop layer 292. In another embodiment, the etching stop layer 292 does not need to be formed before the hard mask layer 294, and instead, after the photoresist layer 296 and the hard mask layer 294 are removed, the etching stop layer 292 is formed covering the second conductivity type semiconductor layer 212.

Next, according to a production demand, for example, in a plasma-enhanced chemical vapor deposition (PECVD) manner, an insulating material is selectively formed covering the etching stop layer 292 and the isolation trenches 216 and 240. The insulating material is, for example, a silicon dioxide or silicon nitride. Subsequently, in an embodiment, for example, in etch-back manner, and by using the etching stop layer 292 as an etching end, the insulating material on the etching stop layer 292 is removed, so as to fill the insulating layers 218 and 242 in the isolation trenches 216 and 240, respectively, as shown in FIG. 11E and FIG. 4. In some embodiments, for example, in a Chemical Mechanical Polishing (CMP) manner, an excessive insulating material on the etching stop layer 292 is removed. At this time, the etching stop layer 292 is taken as a polishing end.

The insulating layers 218 and 242 preferably seal the opening 248 of the isolation trench 216 and the opening 250 of the isolation trench 240, respectively. In an embodiment, as shown in FIG. 11E, the insulating material completely fills the isolation trenches 216 and 240. In another embodiment, the insulating material does not completely fill the isolation trenches 216 and 240, and instead holes are formed in the isolation trenches 216 and 240.

Next, the etching stop layer 292 is removed to expose from the second conductivity type semiconductor layer 212. In an embodiment, the mesa of the LED chip 228 is directly defined. However, in another embodiment, for example, in a deposition manner, a current blocking material is formed selectively covering the insulating layers 218 and 242 and the second conductivity type semiconductor layer 212. Next, for example, in a lithography and etching manner, a portion of the current blocking material on the second conductivity type semiconductor layer 212 is removed, so as to form current blocking layers 222 and 244, as shown in FIG. 11F and FIG. 4. The current blocking layer 222 covers the insulating layer 218 and extends on the second conductivity type semiconductor layer 212 outside the opening 248 of the isolation trench 216. Similarly, the current blocking layer 244 covers the insulating layer 242 and extends on the second conductivity type semiconductor layer 212 outside the opening 250 of the isolation trench 240.

As shown in FIG. 11F, in the embodiment where the current blocking layers 222 and 244 are disposed, subsequently, for example, in a deposition or sputtering manner, the transparent conductive layer 224 is formed covering the current blocking layers 222 and 244 and the second conductivity type semiconductor layer 212. The material of the transparent conductive layer 224 is, for example, an ITO. Next, for example, in a lithography and etching process, for example, an ICP etching process, the mesa of each LED chip 228 is defined. In the process of defining a mesa, a portion of the transparent conductive layer 224, a portion of the second conductivity type semiconductor layer 212, and a portion of the active layer 210 are removed, or even a portion of the first conductivity type semiconductor layer 208 is removed, so as to expose a portion of the first conductivity type semiconductor layer 208 and form the mesa structure 230 and the exposed portion 234 of each LED chip 228. In addition, as shown in FIG. 4, in the process of defining the mesa, the transparent conductive layer 224 on the isolation trench 240 is further removed. After the mesa is defined, the isolation trench 216 of each LED chip 228 is located in the mesa structure 230, and the transparent conductive layer 224 is located on the mesa structure 230.

In another embodiment, the mesa of each LED chip 228 is first defined, the current blocking layers 222 and 244 are then formed, and next the transparent conductive layer 224 is formed. At this time, as shown in FIG. 11G, the current blocking layer 222 is located on the mesa structure 230 and above the isolation trench 216, and covers the insulating layer 218, a portion of the second conductivity type semiconductor layer 212, and the side surface 246 of the mesa structure 230 where the formed subsequently interconnection layer 226 is located. Further, the transparent conductive layer 224 is located on the mesa structure 230, covers the current blocking layer 222, and extends on the second conductivity type semiconductor layer 212 of the mesa structure 230. On the other hand, the current blocking layer 244 is located above the isolation trench 240, and covers the insulating layer 242 inside the isolation trench 240 and the second conductivity type semiconductor layer 212 on the periphery of the opening 250 of the isolation trench 240.

Subsequently, for example, in a deposition manner, the conductive layer is formed covering the mesa structure 230 and the exposed portion 234 of the first conductivity type semiconductor layer 208. Next, for example, in a lithography and etching manner, a portion of the metal layer is removed to form a plurality of interconnection layers 226, the first conductive type electrode pad 238, and the second conductive type electrode pad 236. In another embodiment, as shown in FIG. 2, during the fabrication of the interconnection layer 226, the test pad 258 is fabricated at the same time. The interconnection layer 226 respectively connects adjacent LED chips 228, so as to electrically connects these LED chips 228 in series. The first conductive type electrode pad 238 and the second conductive type electrode pad 236 are disposed on two LED chips of the LED structure 200, respectively, for example, LED chips 228b and 228a in the LED chip array. The first conductive type electrode pad 238 is located on the exposed portion 234 of the first conductivity type semiconductor layer 208 of the LED chip 228b, and is electrically connected to the exposed portion 234 of the first conductivity type semiconductor layer 208. On the other hand, the second conductive type electrode pad 236 is located on the transparent conductive layer 224 or the second conductivity type semiconductor layer 212 on the mesa structure 230 of the LED chip 228a, and is electrically connected to the second conductivity type semiconductor layer 212.

Next, for example, in a deposition manner, the reflective insulating layer 220 is formed covering the interconnection layer 226, the mesa structure 230, the exposed portion 234 of the first conductivity type semiconductor layer 208, the first conductive type electrode pad 238, and the second conductive type electrode pad 236. Referring to FIG. 2 again, for example, by using a patterning technique, the reflective insulating layer 220 is defined to at least form penetration holes 256, 254, and 260 in the reflective insulating layer 220. The three penetration holes 256, 254, and 260 expose a portion of the first conductive type electrode pad 238, a portion of the second conductive type electrode pad 236, and a portion of the test pad 258, respectively. By disposing the penetration hole 260, the LED structure 200 is detected through the test pad 258 exposed from the penetration hole 260.

Next, as shown in FIG. 2 and FIG. 11G, the first conductive type bonding pad 252 and the second conductive type bonding pad 232 are formed on two parts separated from each other of the reflective insulating layer 220, respectively, so as to complete the serially connected LED structure 200. The first conductive type bonding pad 252 and the second conductive type bonding pad 232 are separated from each other. In addition, the first conductive type bonding pad 252 and the second conductive type bonding pad 232 are electrically connected to the exposed first conductive type electrode pad 238 and second conductive type electrode pad 236, respectively, through the penetration holes 256 and 254.

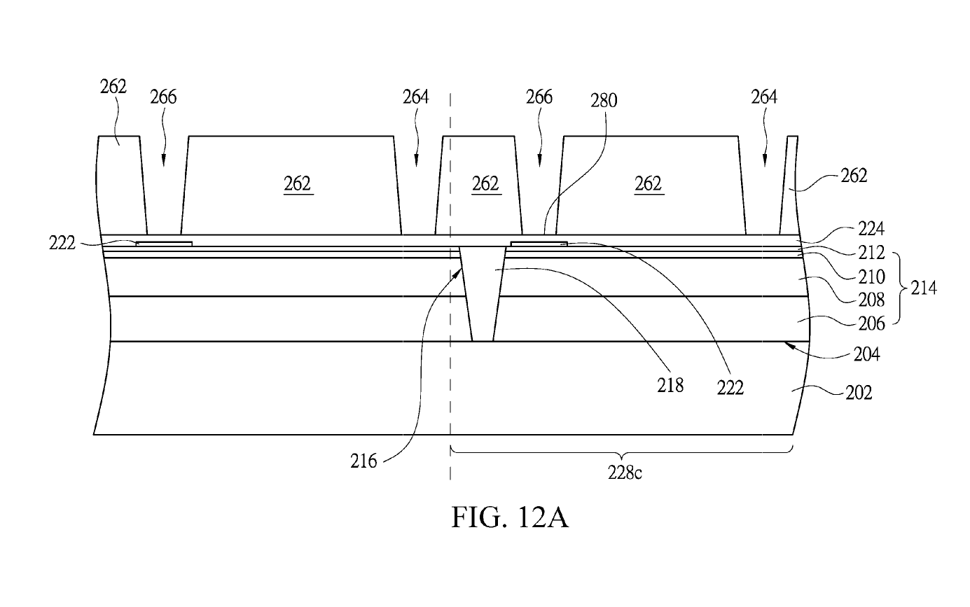

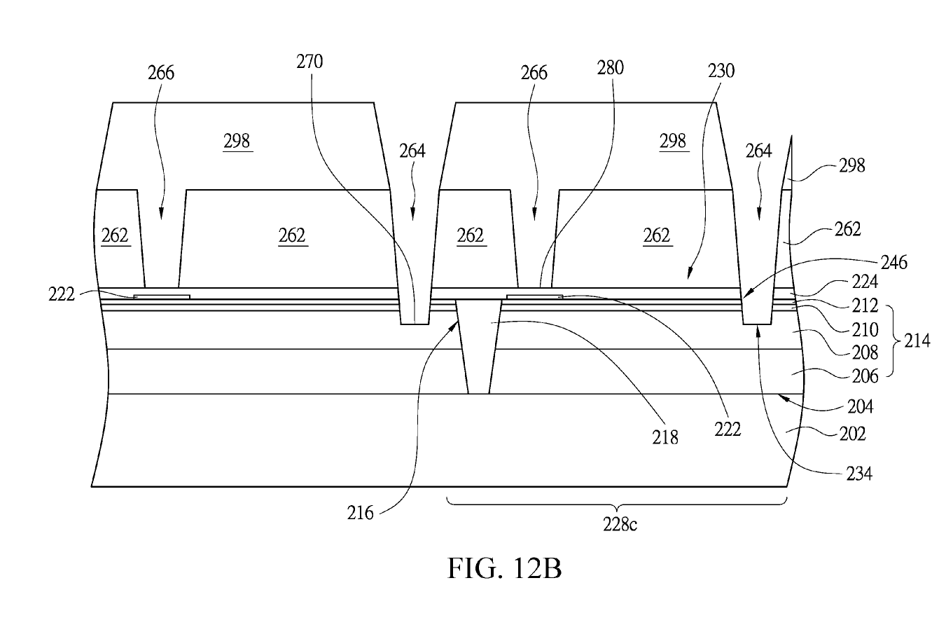

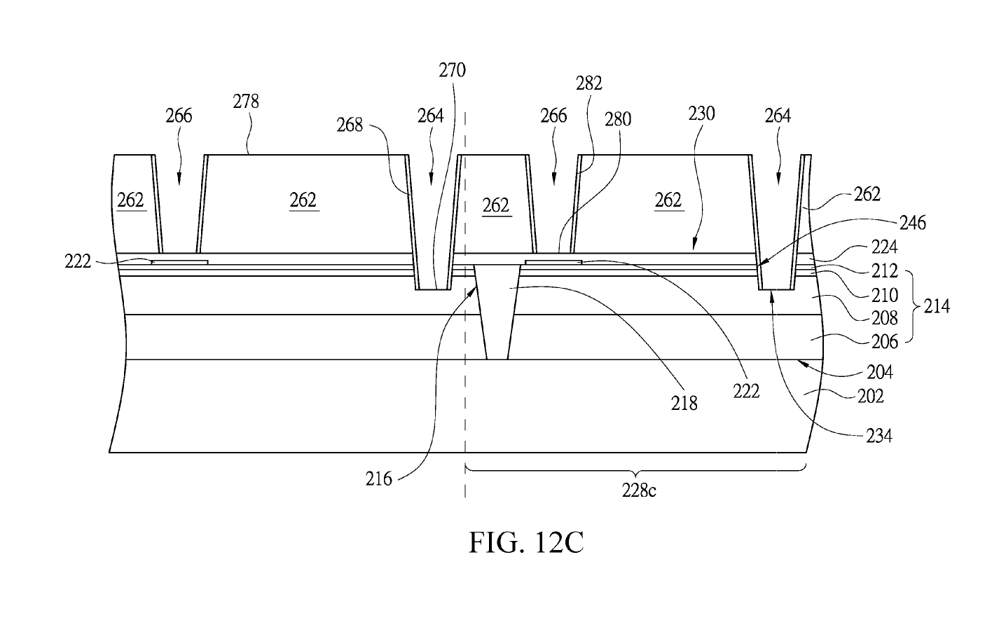

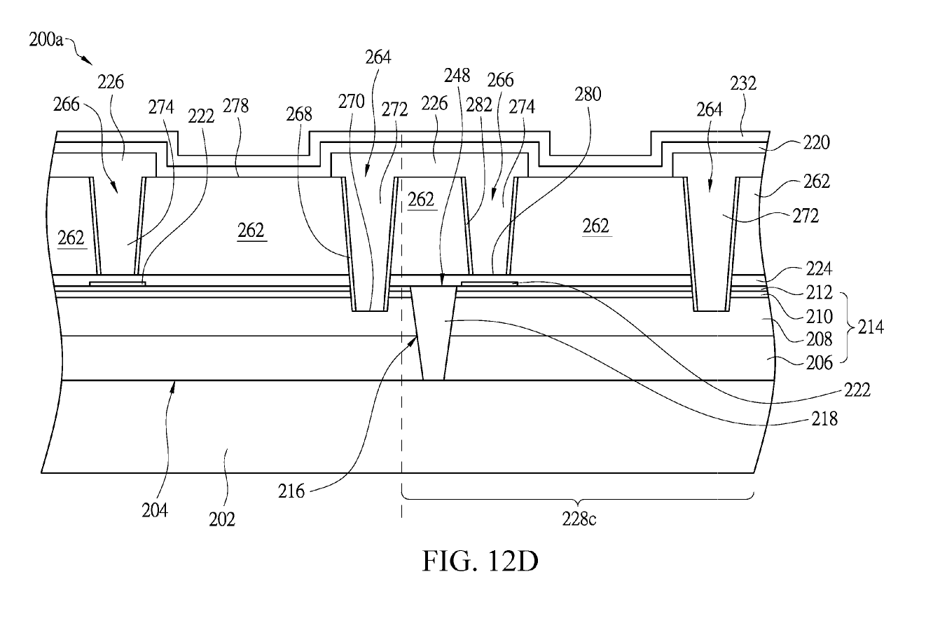

FIGS. 12A-12D are process sectional views of an LED structure according to another embodiment of the present invention. In this embodiment, according to the process steps in the above embodiment, the structure shown in FIG. 11F is first completed. Then, a dielectric material layer is formed covering the transparent conductive layer 224 above the epitaxial layer 214. The dielectric material is an insulating material, for example, a silicon dioxide and silicon nitride. In an embodiment, for example, in a PECVD manner, a dielectric material layer is formed, in which the thickness of the dielectric material layer is about 2000 Å to 3000 Å. In another embodiment, for example, in a spin coating manner, a dielectric material layer is formed, in which the thickness of the dielectric material layer is about 2 μm to 3 μm.

Subsequently, for example, in a CMP manner, according to a practical process demand, planarization processing can be selectively performed on the dielectric material layer, so as to achieve a dielectric material layer with a substantially planar surface. Then, as shown in FIG. 12A, for example, in a lithography and etching manner or in a ICP etching manner, a portion of the dielectric material layer is removed to form a portion of a plurality of first electrical contact holes 264 and a plurality of second electrical contact holes 266, and form a plurality of dielectric layers 262. Each LED chip 228c includes a dielectric layer 262, and a portion of the first electrical contact hole 264 and the second electrical contact hole 266 penetrate the dielectric layer 262.

Next, a photoresist layer 298 is formed covering the dielectric layer 262 and is filled in the first electrical contact hole 264 and the second electrical contact hole 266. Next, for example, by using a lithography process, the pattern of the photoresist layer 298 is defined. When the photoresist layer 298 is being defined, the photoresist layer 298 in the first electrical contact hole 264 is removed, and the transparent conductive layer 224 inside the first electrical contact hole 264 is exposed. Further, for example, in an etching manner, and by using the patterned photoresist layer 298 as an etching mask, the exposed portion of the transparent conductive layer 224 and the second conductivity type semiconductor layer 212, the active layer 210, and a portion of the first conductivity type semiconductor layer 208 there below are removed, so as to complete the first electrical contact hole 264. In this way, the defining of the mesa structure 230 and the exposed portion 234 of the first conductivity type semiconductor layer 208 of each LED chip 228c are completed. As shown in FIG. 12B, the isolation trench 216 of each LED chip 228c is between the second electrical contact hole 266 thereof and an the first electrical contact hole 264 of an adjacent LED chip 228c.

As shown in FIG. 12B, in each LED chip 228c, the bottom 270 of the first electrical contact hole 264 exposes a portion of the first conductivity type semiconductor layer 208, and is located in the first conductivity type semiconductor layer 208. The bottom 280 of the second electrical contact hole 266 exposes a portion of the transparent conductive layer 224. In addition, the current blocking layer 222 is between the second conductivity type semiconductor layer 212 of the epitaxial layer 214 and the bottom 280 of the second electrical contact hole 266. Also, the transparent conductive layer 224 covers the current blocking layer 222, and is between the second conductivity type semiconductor layer 212 of the epitaxial layer 214 and dielectric layer 262. In another embodiment, the LED chip 228c does not have a transparent conductive layer, and the bottom 280 of the second electrical contact hole 266 exposes a portion of the second conductivity type semiconductor layer 212.

Next, the residual photoresist layer 298 is removed to expose the dielectric layer 262, the first electrical contact hole 264, and the second electrical contact hole 266. For example, in a PECVD manner, an insulating material layer is then formed covering the dielectric layer 262, the sidewall and bottom 270 of the first electrical contact hole 264, and the sidewall and bottom 280 of the second electrical contact hole 266. The material of the insulating material layer is, for example, a silicon dioxide or silicon nitride. Subsequently, in an anisotropic etching manner such as dry etching, the insulating material layers on the upper surface 278 of the dielectric layer 262, the bottom 270 of the first electrical contact hole 264, and the bottom 280 of the second electrical contact hole 266 are removed, so as to form insulating lining layers 268 and 282 on the sidewall of the first electrical contact hole 264 and the sidewall of the second electrical contact hole 266, respectively, as shown in FIG. 12C.

Subsequently, for example, in a deposition manner, a conductive layer is formed covering the upper surface 278 of the dielectric layer 262, and is filled in the first electrical contact hole 264 and the second electrical contact hole 266. Referring to FIG. 12D and FIG. 2 at the same time, for example, in a lithography and etching manner, a portion of the metal layer is then removed to form a plurality of interconnection layers 226, the first conductive type electrode pad 238, and the second conductive type electrode pad 236. The portions filled in the first electrical contact hole 264 and the second electrical contact hole 266 of each interconnection layer 226 are also referred to contact plugs 272 and 274, respectively.

Subsequently, for example, in a deposition manner, the reflective insulating layer 220 is formed covering the interconnection layer 226 and the upper surface 278 of the dielectric layer 262. Referring to FIG. 2 again, for example, by using a patterning technique, the reflective insulating layer 220 is defined to at least form penetration holes 256, 254, and 260 in the reflective insulating layer 220. The three penetration holes 256, 254, and 260 expose a portion of the first conductive type electrode pad 238, a portion of the second conductive type electrode pad 236, and a portion of the test pad 258, respectively.

Next, as shown in FIG. 2 and FIG. 12D, the first conductive type bonding pad 252 and the second conductive type bonding pad 232 separated from each other are formed on the reflective insulating layer 220, so as to complete the serially connected LED structure 200a. The first conductive type bonding pad 252 and the second conductive type bonding pad 232 are separated from each other. In addition, the first conductive type bonding pad 252 and the second conductive type bonding pad 232 contact and are electrically connected to the exposed first conductive type electrode pad 238 and second conductive type electrode pad 236 through the penetration holes 256 and 254, respectively.

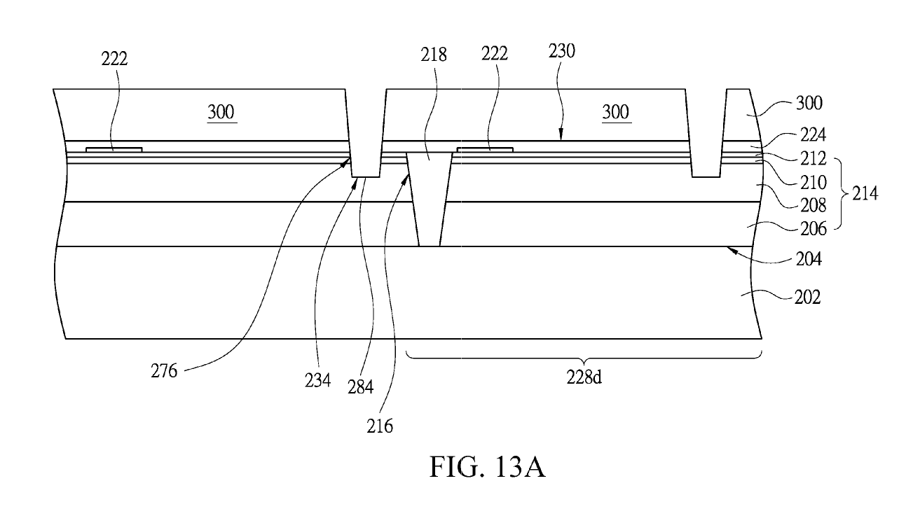

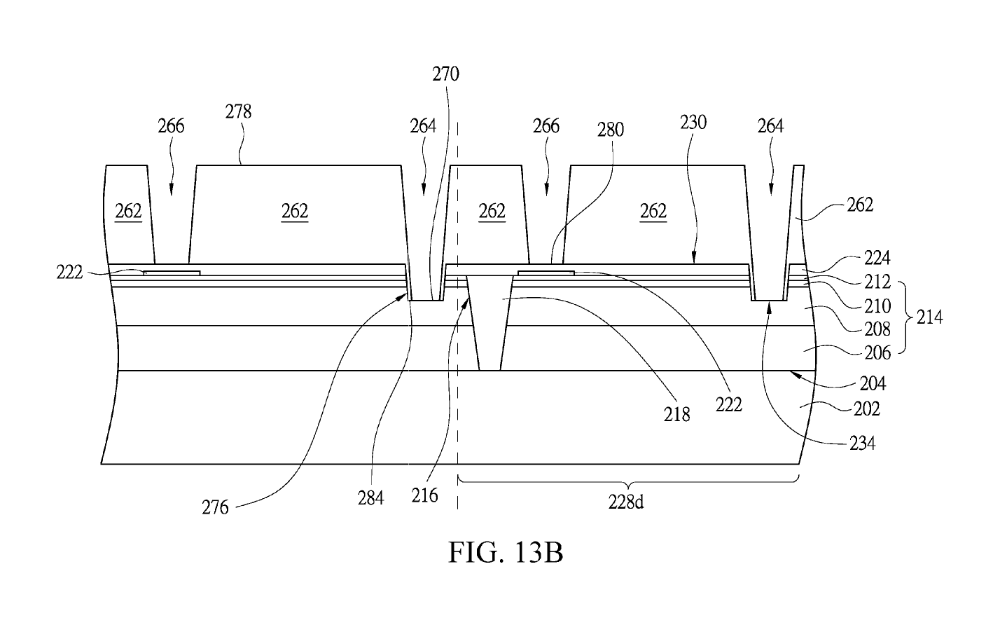

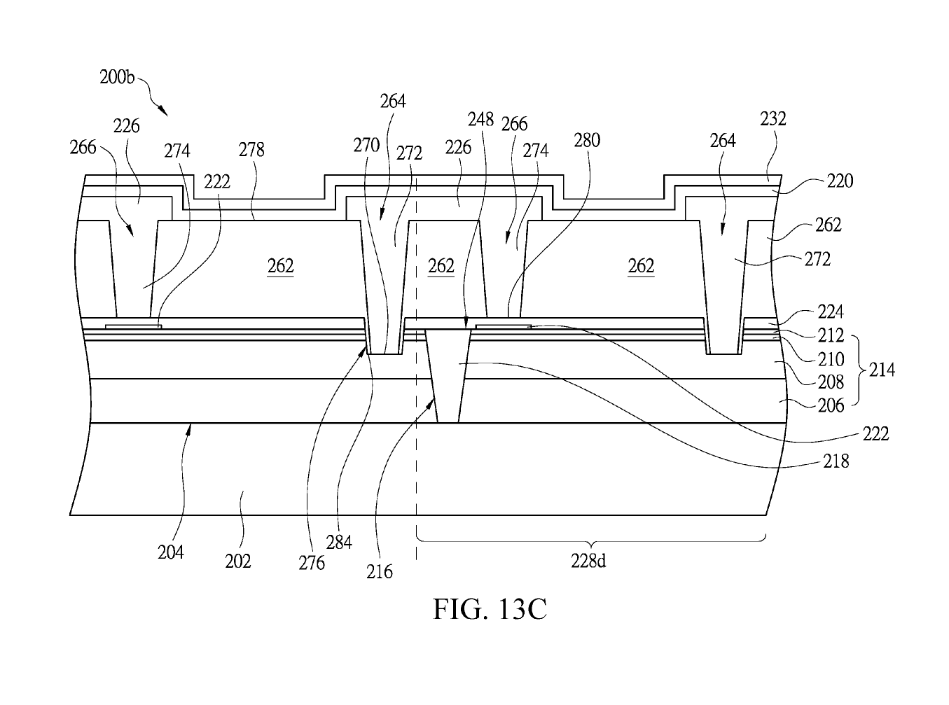

FIGS. 13A-13C are process sectional views of an LED structure according to a further embodiment of the present invention. In this embodiment, according to the process steps in the above embodiment, the structure shown in FIG. 11F is first completed. First, for example, in a coating manner, a photoresist layer 300 is formed covering the transparent conductive layer 224. Next, for example, by using a lithography process, the pattern of the photoresist layer 300 is defined. When the photoresist layer 300 is being defined, a portion of the photoresist layer 300 is removed to expose a portion of the transparent conductive layer 224, so as to define the predetermined position and shape of the groove 276 in the photoresist layer 300. Next, as shown in FIG. 13A, for example, in an etching manner, and by using the patterned photoresist layer 300 as an etching mask, the exposed portion of transparent conductive layer 224, and a portion of the second conductivity type semiconductor layer 212, a portion of the active layer 210, and a portion of the first conductivity type semiconductor layer 208 there below, are removed, so as to form the groove 276 in the epitaxial layer 214. The bottom 284 of the groove 276 exposes a portion of the first conductivity type semiconductor layer 208. Therefore, the defining of the epitaxial layer 214, the mesa structure 230, and the exposed portion 234 of the first conductivity type semiconductor layer 208 of each LED chip 228d are completed.

Subsequently, the residual photoresist layer 300 is removed to expose the transparent conductive layer 224 and the groove 276. Next, for example, in a PECVD manner or spin coating manner, a dielectric material layer is formed covering the transparent conductive layer 224 and is filled in the groove 276. The dielectric material is an insulating material such as a silicon dioxide and silicon nitride. After the dielectric material layer is formed, according to a practical process requirement, for example, in a CMP manner, planarization processing is selectively performed on the dielectric material layer, so as to obtain a dielectric material layer with a substantially planar surface.

Subsequently, as shown in FIG. 13B, for example, in a lithography and etching manner, for example, an ICP etching manner, a portion of the dielectric material layer is removed to form a plurality of first electrical contact holes 264 and a plurality of second electrical contact holes 266, and form a plurality of dielectric layers 262. Each LED chip 228c includes a dielectric layer 262, and the first electrical contact hole 264 and the second electrical contact hole 266 penetrate the dielectric layer 262.

As shown in FIG. 13B, in each LED chip 228d, a portion of the dielectric layer 262 covers the sidewall of the groove 276, and the bottom 270 of the first electrical contact hole 264 exposes a portion of the bottom 284 of the groove 276. The bottom 280 of the second electrical contact hole 266 exposes a portion of the transparent conductive layer 224. In this embodiment, because the dielectric layer 262 extends to cover the sidewall of the groove 276, in the LED structure 200b (referring to FIG. 13C first), an insulating lining layer does not need to be otherwise disposed on the sidewall of the first electrical contact hole 264, and the interconnection layer 226 is electrically insulated from the epitaxial layer 214 and the transparent conductive layer 224 exposed from the sidewall of the groove 276.

Subsequently, for example, in a deposition manner, a conductive layer is formed covering the upper surface 278 of the dielectric layer 262, and is filled in the first electrical contact hole 264 and the second electrical contact hole 266. For example, in a lithography and etching manner, a portion of the metal layer is removed to form a plurality of interconnection layers 226, the first conductive type electrode pad, and the second conductive type electrode pad (for example, the first conductive type electrode pad 238 and the second conductive type electrode pad 236 as shown in FIG. 2), so as to complete the serially connected LED structure 200b, as shown in FIG. 13C.

As shown in FIG. 13C, the interconnection layer 226 extends from the exposed portion of the first conductivity type semiconductor layer 208 in the first electrical contact hole 264 of one LED chip 228d of two adjacent LED chips 228d through the upper surface 278 of the dielectric layer 262 above the isolation trench 216 of the adjacent LED chip 228d and is filled in the second electrical contact hole 266 of the adjacent LED chip 228d, and contacts the exposed portion of the transparent conductive layer 224 of the adjacent LED chip 228d. Therefore, the interconnection layer 226 electrically connects two adjacent LED chips 228d.

Subsequently, for example, in a deposition manner, a reflective insulating layer 220 is formed covering the interconnection layer 226 and the upper surface 278 of the dielectric layer 262. Referring to FIG. 2 again, for example, by using a patterning technique, the reflective insulating layer 220 is defined to at least form penetration holes 256, 254, and 260 in the reflective insulating layer 220. The three penetration holes 256, 254, and 260 expose a portion of the first conductive type electrode pad 238, a portion of the second conductive type electrode pad 236, and a portion of the test pad 258, respectively.

Next, as shown in FIG. 2 and FIG. 13C, the first conductive type bonding pad 252 and the second conductive type bonding pad 232 separated from each other are formed on the reflective insulating layer 220, respectively, so as to complete the serially connected LED structure 200b. The first conductive type bonding pad 252 and the second conductive type bonding pad 232 are separated from each other. In addition, the first conductive type bonding pad 252 and the second conductive type bonding pad 232 contact and are electrically connected to the exposed first conductive type electrode pad 238 and second conductive type electrode pad 236, respectively, through the penetration holes 256 and 254.

As can be seen from the above embodiments, one advantage of the present invention is that the LED structure is formed by serially connecting a plurality of LED chips, therefore having the advantages such as dense arrangement and high light efficiency.

As can be seen from the above embodiments, another advantage of the present invention is that, as the LED structure includes a reflective insulating layer covering the interconnection layer, the mesa structure, and the exposed portion of the first conductivity type semiconductor layer of each LED chip, the packaging can be performed in a flip chip manner, thereby achieving the efficacies such as high heat dissipation, wire-free bonding, and low thermal resistance.

As can be seen from the above embodiments, a further advantage of the present invention is that, as the interconnection layer extends, from the first conductivity type semiconductor layer of one of adjacent LED chips, directly through the side surface of the mesa structure of another LED chip, on the mesa structure, the aspect ratio of the interconnection layer is significantly reduced, the step coverage capability during the deposition of the interconnection layer is effectively enhanced, and further it can be avoided that disconnections occur during the deposition of the interconnection layer.

As can be seen from the above embodiment, yet a further advantage of the present invention is that, as the mesa structure of the LED chip has an inclined trapezoidal side surface, the step coverage capability of the interconnection layer is further enhanced, and the problem of disconnections in an interconnection layer is solved more effectively.

As can be seen from the above embodiment, yet a further advantage of the present invention is that, as the light emission area of the LED chip and the first conductivity type semiconductor layer of the adjacent LED chip are separated by an isolation trench, only an insulating layer but no conductive material is filled in the isolation trench, and furthermore, a current blocking layer can be additionally disposed on the opening of the isolation trench for electrical isolation, even if the deposition of the insulating layer inside the isolation trench is discontinuous, in the case of no conductive material inside the isolation trench, the problem of a short circuit does not occur in the light emission area.

As can be seen from the above embodiment, yet a further advantage of the present invention is that, as the interconnection layer directly extends, from the contact hole in the dielectric layer above one of adjacent LED chips, through the above of the dielectric layer, to the contact hole in the dielectric layer above another of adjacent LED chips, a conductive material does not need to be filled in the isolation trough between two adjacent LED chips, thereby solving the problem of disconnections in an interconnection layer.

As can be seen from the above embodiment, yet a further advantage of the present invention is that, as the problems of a short circuit and a disconnection are effectively solved, the production yield of the serially-connected LED structure is significantly enhanced, and further the fabrication cost is reduced.

As can be seen from the above embodiment, yet a further advantage of the present invention is that, as the problems of a short circuit and a disconnection are effectively solved, without depending on a means of detecting a reverse leakage current, a short circuit defect in an LED structure can be successfully confirmed by detecting forward/reverse currents.

The foregoing description of the exemplary embodiments of the invention has been presented only for the purposes of illustration and description and is not intended to be exhaustive or to limit the invention to the precise forms disclosed. Many modifications and variations are possible in light of the above teaching.

The embodiments are chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A light-emitting diode (LED) structure, comprising:
an insulation substrate;
a plurality of LED chips, wherein each of the LED chips comprises an epitaxial layer, the epitaxial layer comprises a first conductivity type semiconductor layer, an active layer, and a second conductivity type semiconductor layer sequentially stacked on a surface of the insulation substrate, wherein each of the LED chips comprises a mesa structure and an exposed portion of the first conductivity type semiconductor layer adjacent to each other, wherein a first isolation trench is defined by two adjacent LED chips in a first direction, and wherein the first isolation trench is disposed in the mesa structure;
a plurality of interconnection layers, connecting two adjacent LED chips of the LED chips, respectively;
a first conductive type electrode pad and a second conductive type electrode pad, disposed on a first LED chip and a second LED chip of the LED chips, respectively, and electrically connected to the exposed portion of the first conductivity type semiconductor layer of the first LED chip and the second conductivity type semiconductor layer of the second LED chip, respectively;
a reflective insulating layer, covering the interconnection layers, the mesa structures, the first conductive type electrode pad, and the second conductive type electrode pad, wherein the reflective insulating layer has at least one first penetration hole and at least one second penetration hole exposing a portion of the first conductive type electrode pad and a portion of the second conductive type electrode pad, respectively;
a first conductive type bonding pad, located on a portion of the reflective insulating layer, and electrically connected to the first conductive type electrode pad through the at least one first penetration hole; and
a second conductive type bonding pad, located on another portion of the reflective insulating layer, separated from the first conductive type bonding pad, and electrically connected to the second conductive type electrode pad through the at least one second penetration hole.

2. The LED structure according to claim 1, wherein each of the LED chips further comprises an insulating layer, and the insulating layer is filled in the first isolation trench, so as to seal an opening of the first isolation trench.

3. The LED structure according to claim 2, wherein each of the LED chips further comprises a current blocking layer between the interconnection layer on the mesa structure and the insulating layer.

4. The LED structure according to claim 3, wherein each of the LED chips further comprises a transparent conductive layer extending on the second conductivity type semiconductor layer of the mesa structure, and being between the interconnection layer on the mesa structure and the current blocking layer.

5. The LED structure according to claim 1,
wherein each of the LED chips further comprises a dielectric layer disposed on the epitaxial layer, and each of the LED chips is provided with a first electrical contact hole and a second electrical contact hole penetrating the dielectric layer;
wherein the first isolation trench is between the second electrical contact hole of the LED chip and the first electrical contact hole of the adjacent LED chip;
wherein each of the interconnection layers extends, from the second electrical contact hole of each of the LED chips, above the first isolation trench, into the first electrical contact hole of the adjacent LED chip; and
wherein the reflective insulating layer further covers the dielectric layer.

6. The LED structure according to claim 5,
wherein each of the LED chips further comprises a transparent conductive layer between the dielectric layer and the epitaxial layer;
wherein a bottom of the first electrical contact hole exposes the exposed portion of the first conductivity type semiconductor layer; and
wherein a bottom of the second electrical contact hole exposes the transparent conductive layer.

7. The LED structure according to claim 6, wherein each of the LED chips further comprises at least one current blocking layer between the bottom of the second electrical contact hole and the epitaxial layer.

8. The LED structure according to claim 5, wherein in each of the LED chips, the epitaxial layer has a groove, a bottom of the groove exposes the exposed portion of the first conductivity type semiconductor layer, the first electrical contact hole exposes a portion of the bottom of the groove, and the dielectric layer covers a sidewall of the groove.

9. The LED structure according to claim 5, wherein each of the LED chips further comprises at least one insulating lining layer covering a sidewall of the first electrical contact hole.

10. The LED structure according to claim 1,
wherein a second isolation trench is defined by two adjacent LED chips in a second direction;
wherein the first isolation trenches abut the second isolation trenches; and
wherein an epitaxial layer of each LED chip is separated from an epitaxial layer of an adjacent LED chip by the first isolation trench and the second isolation trench.

11. A method for manufacturing a light-emitting diode (LED) structure, comprising:
providing an insulation substrate;
forming an epitaxial structure, wherein the epitaxial structure comprises a first conductivity type semiconductor layer, an active layer, and a second conductivity type semiconductor layer sequentially stacked on a surface of the insulation substrate;
forming a plurality of first isolation trenches and a plurality of second isolation trenches in the epitaxial structure, so as to define a plurality of epitaxial layers of a plurality of LED chips, wherein the first isolation trenches abut the second isolation trenches, respectively;
removing a portion of the second conductivity type semiconductor layer and a portion of the active layer, so as to define a mesa structure and an exposed portion of the first conductivity type semiconductor layer of each of the LED chips, wherein each of the LED chips comprises one of the first isolation trenches, and the one of the first isolation trenches is disposed in the mesa structure;
forming a plurality of interconnection layers, a first conductive type electrode pad, and a second conductive type electrode pad, wherein the interconnection layers connect two adjacent LED chips of the LED chips, respectively, the first conductive type electrode pad and the second conductive type electrode pad are disposed on a first and a second of the LED chips, respectively, and the first conductive type electrode pad and the second conductive type electrode pad are electrically connected to the exposed portion of the first conductivity type semiconductor layer of the first LED chip and the second conductivity type semiconductor layer of the second LED chip, respectively;
forming a reflective insulating layer covering the interconnection layers, the mesa structures, the first conductive type electrode pad, and the second conductive type electrode pad, wherein the reflective insulating layer has at least one first penetration hole and at least one second penetration hole exposing a portion of the first conductive type electrode pad and a portion of the second conductive type electrode pad, respectively;
forming a first conductive type bonding pad on a portion of the reflective insulating layer, wherein the first conductive type bonding pad is electrically connected to the first conductive type electrode pad through the at least one first penetration hole; and
forming a second conductive type bonding pad on another portion of the reflective insulating layer, wherein the second conductive type bonding pad and the first conductive type bonding pad are separated from each other, and the second conductive type bonding pad is electrically connected to the second conductive type electrode pad through the at least one second penetration hole.

12. The method according to claim 11, after forming the first isolation trenches and the second isolation trenches in the epitaxial structure, further comprising forming a plurality of dielectric layers covering the epitaxial layers, respectively, wherein each of the LED chips has a first electrical contact hole and a second electrical contact hole penetrating the dielectric layer, and the first isolation trench is between the second electrical contact hole of the LED chip and the first electrical contact hole of an adjacent LED chip.

13. The method according to claim 12, before forming the dielectric layers, further comprising:
forming a plurality of transparent conductive layers between the dielectric layers and the epitaxial layers, respectively; and
forming a plurality of current blocking layers located between the epitaxial layers and the transparent conductive layers, respectively;
wherein in each of the LED chips, a bottom of the first electrical contact hole exposes the first conductivity type semiconductor layer, a bottom of the second electrical contact hole exposes the transparent conductive layer, and the current blocking layers are correspondingly disposed at positions below the bottoms of the second electrical contact holes.

14. A light-emitting diode (LED) structure, comprising:
an insulation substrate;
a plurality of LED chips, wherein each of the LED chips comprises an epitaxial layer, the epitaxial layer comprises a first conductivity type semiconductor layer, an active layer, and a second conductivity type semiconductor layer sequentially stacked on a surface of the insulation substrate, wherein each of the LED chips comprises a mesa structure and an exposed portion of the first conductivity type semiconductor layer adjacent to each other, and a first isolation trench, and wherein the first isolation trench is disposed in the mesa structure;
a plurality of interconnection layers, connecting two adjacent LED chips of the LED chips, respectively;
a first conductive type electrode pad and a second conductive type electrode pad disposed on a first LED chip and a second LED chip of the LED chips, respectively, and electrically connected to the exposed portion of the first conductivity type semiconductor layer of the first LED chip and the second conductivity type semiconductor layer of the second LED chip, respectively;
an insulating layer, covering the interconnection layers, the mesa structures, the first conductive type electrode pad, and the second conductive type electrode pad, wherein the insulating layer has at least one first penetration hole and at least one second penetration hole exposing a portion of the first conductive type electrode pad and the second conductive type electrode pad, respectively;
a first conductive type bonding pad, located on a portion of the insulating layer, and electrically connected to the first conductive type electrode pad through the at least one first penetration hole; and
a second conductive type bonding pad, located on another portion of the insulating layer, separated from the first conductive type bonding pad, and electrically connected to the second conductive type electrode pad through the at least one second penetration hole.

15. The LED structure according to claim 14, wherein the insulating layer is a distributed Bragg reflector (DBR).

16. The LED structure according to claim 14, further comprising a reflective insulating layer,
wherein each of the LED chips further comprises a dielectric layer disposed on the epitaxial layer, each of the LED chips is provided with a first electrical contact hole and a second electrical contact hole penetrating the dielectric layer, and the first isolation trench is between the second electrical contact hole of the LED chip and the first electrical contact hole of the adjacent LED chip;
wherein the reflective insulating layer covers a sidewall of the first electrical contact hole, a sidewall of the second electrical contact hole, and an upper surface of the dielectric layer of each of the LED chips; and
wherein each of the interconnection layers extends, from the second electrical contact hole of each of the LED chips, above the first isolation trench, into the first electrical contact hole of the adjacent LED chip.

17. The LED structure according to claim 14, further comprising a reflective insulating layer,
wherein each of the LED chips further comprises a dielectric layer disposed on the epitaxial layer, each of the LED chips is provided with a first electrical contact hole and a second electrical contact hole penetrating the dielectric layer, the first isolation trench is between the second electrical contact hole of the LED chip and the first electrical contact hole of the adjacent LED chip, the epitaxial layer has a groove, a bottom of the groove exposes the exposed portion of the first conductivity type semiconductor layer, and the first electrical contact hole exposes a portion of the bottom of the groove;
wherein the reflective insulating layer covers a sidewall of each of the grooves and an upper surface of each of the epitaxial layers; and
wherein each of the interconnection layers extends, from the second electrical contact hole of each of the LED chips, above the first isolation trench, into the first electrical contact hole of the adjacent LED chip.

18. The LED structure according to claim 14, further comprising a reflective insulating layer,
wherein each of the LED chips further comprises a dielectric layer disposed on the epitaxial layer, each of the LED chips is provided with a first electrical contact hole and a second electrical contact hole penetrating the dielectric layer, the first isolation trench is between the second electrical contact hole of the LED chip and the first electrical contact hole of the adjacent LED chip, the epitaxial layer has a groove, a bottom of the groove exposes the exposed portion of the first conductivity type semiconductor layer, the first electrical contact hole exposes a portion of the bottom of the groove, and the dielectric layer covers a sidewall of the groove;
wherein the reflective insulating layer covers an upper surface of each of the epitaxial layers; and
wherein each of the interconnection layers extends, from the second electrical contact hole of each of the LED chips, above the first isolation trench, to the first electrical contact hole of the adjacent LED chip.

19. The LED structure according to claim 14, further comprising a reflective insulating layer,
wherein each of the LED chips further comprises a dielectric layer disposed on the epitaxial layer, each of the LED chips is provided with a first electrical contact hole and a second electrical contact hole penetrating the dielectric layer, the first isolation trench is between the second electrical contact hole of the LED chip and the first electrical contact hole of the adjacent LED chip, the epitaxial layer has a groove, a bottom of the groove exposes the exposed portion of the first conductivity type semiconductor layer, the first electrical contact hole exposes a portion of the bottom of the groove, and the dielectric layer covers a sidewall of the groove;
wherein the reflective insulating layer covers an upper surface of each of the dielectric layers; and
wherein each of the interconnection layers extends, from the second electrical contact hole of each of the LED chips, above the first isolation trench, to the first electrical contact hole of the adjacent LED chip.
